(19) United States
(12) Patent Application Publication
(10) Pub. No.: US 2026/0334242 A1
(43) Pub. Date: Oct. 22, 2026

(54) SEMICONDUCTOR PACKAGE

(71) Applicant: SAMSUNG ELECTRONICS CO., LTD., Suwon-si (KR)

(72) Inventors: Keunyoung LEE, Suwon-si (KR); Taeyoung LEE, Suwon-si (KR)

(73) Assignee: SAMSUNG ELECTRONICS CO., LTD., Suwon-si (KR)

(21) Appl. No.: 19/529,485

(22) Filed: Feb. 4, 2026

(30) Foreign Application Priority Data
Feb. 17, 2025 (KR) 10-2025-0020373

(51) Int. Cl. H10W 46/00; H10B 80/00; H10W 72/90; H10W 90/00; H10W 90/24

(52) U.S. Cl. CPC H10W 46/401; H10W 46/201; H10W 72/9445; H10W 90/24; H10B 80/00; H10W 90/752; H10W 90/754

(57) ABSTRACT

A semiconductor package is provided. The semiconductor package includes a package substrate and a plurality of semiconductor chips stacked on the package substrate in a stepwise manner. Each semiconductor chip includes a plurality of chip pads and an identification pad array. The identification pad array includes a plurality of identification pads electrically connected in series, with an identification resistor electrically connected between every two adjacent identification pads. One or more wire balls may be provided in the identification pad array. Each wire ball is disposed on adjacent identification pads and electrically connects the adjacent identification pads to each other.

### CROSS-REFERENCE TO RELATED APPLICATION

This application is based on and claims priority under 35 U.S.C. § 119 to Korean Patent Application No. 10-2025-0020373, filed on Feb. 17, 2025, in the Korean Intellectual Property Office, the disclosure of which is incorporated by reference herein in its entirety.

### BACKGROUND

The inventive concept relates to a semiconductor package, and more particularly, to a semiconductor package including a plurality of stacked semiconductor chips.

Due to the rapid development of the electronics industry and user needs, electronic devices are becoming more compact and lightweight, and as a result, high integration and large capacity of semiconductor devices, which are core components of electronic devices, are required, but high integration of semiconductor devices is reaching a limit. Accordingly, a semiconductor package including a plurality of semiconductor chips has been developed to achieve large capacity. As the demand for large capacity of semiconductor devices increases further, semiconductor packages including a plurality of stacked semiconductor chips are being developed.

Semiconductor packages are used, in which a plurality of semiconductor chips are stacked in each of the semiconductor packages, and electrical input/output is achieved through wire bonding between a plurality of chips and a package substrate. In addition, a method of connecting stacked semiconductor chips to a package substrate through wiring formed by patterning rather than wire bonding is being considered.

### SUMMARY

The inventive concept provides a semiconductor package having a relatively small size while arranging pads that identify a plurality of semiconductor chips in a plurality of stacked semiconductor stacks.

The task to be solved by the technical idea of the inventive concept is not limited to the above-mentioned task, and other tasks not mentioned may be clearly understood by those of ordinary skill in the art from the following description.

According to an aspect of the inventive concept, there is provided a semiconductor package including a package substrate, and a plurality of semiconductor chips stacked on the package substrate in a stepwise manner, wherein each of the plurality of semiconductor chips includes a plurality of chip pads and an identification pad array, the identification pad array includes a plurality of identification pads, the plurality of identification pads are electrically connected in series, an identification resistor is electrically connected between every two adjacent identification pads of the plurality of identification pads, a wire ball is not provided in the identification pad array, or at least one wire ball is provided in the identification pad array, the wire ball is provided on adjacent identification pads, the wire ball electrically connects adjacent identification pads to each other, a power source is connected to one end of the series connection of the plurality of identification pads, a ground is connected to the other end of the series connection of the plurality of identification pads, and a reference resistor is provided between the plurality of identification pads and the ground.

In addition, according to another aspect of the inventive concept, there is provided a semiconductor package including a package substrate, and a plurality of semiconductor chips stacked on the package substrate in a stepwise manner, wherein each of the plurality of semiconductor chips includes a plurality of chip pads and an identification pad array, the identification pad array includes a plurality of identification pads, the plurality of identification pads are electrically connected in series, an identification resistor may be provided between every two adjacent identification pads of the plurality of identification pads, and the plurality of identification pads and the identification resistor may be electrically connected to each other, an identification pattern is not provided in the identification pad array, or one identification pattern is provided therein, the identification pattern is provided on two or more identification pads, the identification pattern electrically connects two or more identification pads, a power source is connected to one end of the series connection of the plurality of identification pads, a ground is connected to the other end of the series connection of the plurality of identification pads, and a reference resistor is provided between the plurality of identification pads and the ground, power from the power source is the same in all of the plurality of semiconductor chips, each of the plurality of semiconductor chips includes a measurement point at which a voltage applied across the reference resistor is measured, and each of the plurality of semiconductor chips is identified based on the voltage measured at the measurement point.

In addition, according to another aspect of the inventive concept, there is provided a semiconductor package including a package substrate, and a plurality of semiconductor chips stacked on the package substrate in a stepwise manner, wherein each of the plurality of semiconductor chips includes a plurality of chip pads and an identification pad array, a plurality of conductive wires electrically connecting a plurality of chip pads provided in each of the plurality of semiconductor chips is provided, the identification pad array includes a plurality of identification pads, the plurality of identification pads are electrically connected in series, an identification resistor is electrically connected between every two adjacent identification pads of the plurality of identification pads, a wire ball is not provided in the identification pad array, or at least one wire ball is provided in the identification pad array, the wire ball electrically connects adjacent identification pads to each other, the wire ball is in continuous contact with two adjacent identification pads and a top surface of each of the semiconductor chips, power is connected to one end of the series connection of the plurality of identification pads, the ground is connected to the other end of the series connection of the plurality of identification pads, and a reference resistor is provided between the plurality of identification pads and the ground, the identification pad arrays respectively provided in the plurality of semiconductor chips include different numbers of wire balls, each of the plurality of semiconductor chips includes a measurement point at which a voltage applied across the reference resistor is measured, each of the plurality of semiconductor chips has a different voltage applied across the reference resistor, as more of the wire balls are arranged, the lower a magnitude of voltage applied to the reference resistor, the number of wire balls provided in the identification pad array provided in each of the plurality of semiconductor chips varies for each of the plurality of semiconductor chips, a maximum number of the wire balls is less by one than the number of the identification pads provided in the identification pad array, the wire ball is a contact point of the conductive wire, the plurality of identification pads are aligned, the plurality of identification pads have a rectangular shape having a long length in one direction, a diameter of the wire ball is greater in a plan view than a spaced distance between adjacent identification pads of the plurality of identification pads, sizes of the plurality of identification pads in one direction are smaller than sizes of the plurality of chip pads in the one direction, a passivation layer is provided on a top surface of each of the plurality of semiconductor chips, the passivation layer covers the top surfaces of the plurality of semiconductor chips, the plurality of identification pads are spaced apart from the passivation layer, a gap between every two adjacent identification pads of the plurality of identification pads falls within a range of about 20 μm to about 40 μm, and a size of each of the identification pads in one direction corresponds to a range of about 50 μm to about 80 μm.

### BRIEF DESCRIPTION OF THE DRAWINGS

Embodiments will be more clearly understood from the following detailed description taken in conjunction with the accompanying drawings in which:

FIG. 1 is a perspective view showing a semiconductor package according to embodiments.

FIG. 2 is an enlarged plan view of a portion of a semiconductor package according to embodiments.

FIG. 3A is an enlarged plan view of a portion of a semiconductor package according to embodiments.

FIG. 3B is an enlarged plan view of a portion of a semiconductor package according to embodiments.

FIG. 3C is a cross-sectional view taken along line C-C′ of FIG. 3B.

FIG. 3D is an enlarged plan view of a portion of a semiconductor package according to embodiments.

FIG. 3E is an enlarged plan view of a portion of a semiconductor package according to embodiments.

FIGS. 3F and 3G are respective enlarged plan views of a portion of a semiconductor package according to embodiments.

FIG. 4A is a graph illustrating a relative value of a voltage level that may be measured at a measurement point of a semiconductor package according to embodiments.

FIG. 4B is a graph illustrating a relative value of a voltage level that may be measured at a measurement point of a semiconductor package according to embodiments.

FIG. 5 is a perspective view showing a semiconductor package according to embodiments.

FIGS. 6A to 6D are respective enlarged plan views of a portion of a semiconductor package according to embodiments.

FIG. 7 is a perspective view showing a semiconductor package according to embodiments.

FIG. 8 is an enlarged plan view of a portion of a semiconductor package according to embodiments.

FIGS. 9A to 9D are respective enlarged plan views of a portion of a semiconductor package according to embodiments.

FIG. 10 is a perspective view showing a semiconductor package according to embodiments.

FIG. 11 is an enlarged plan view of a portion of a semiconductor package according to embodiments.

FIGS. 12A to 12F are respective enlarged plan views of a portion of a semiconductor package according to embodiments; and

FIG. 13 is a perspective view showing a semiconductor package according to embodiments.

### DETAILED DESCRIPTION OF THE EMBODIMENTS

Hereinafter, embodiments of the technical idea of the inventive concept will be described in detail with reference to the accompanying drawings.

Embodiments of the technical idea of the inventive concept are provided to more completely explain the technical idea of the inventive concept to one of ordinary skill in the art, and the following embodiments may be modified in various different forms, and the scope of the technical idea of the inventive concept is not limited to the following embodiments. Rather, these embodiments are provided to make the present disclosure more faithful and complete, and to fully convey the spirit of the inventive concept to one of ordinary skill in the art. In addition, the thickness or size of each layer in the drawings is exaggerated for convenience and clarity of explanation.

In the present specification, the first direction may refer to an X-direction, the second direction may refer to a Y-direction, and the first direction and the second direction may be perpendicular to each other. The third direction may be a Z-direction, and the third direction may be perpendicular to each of the first direction and the second direction. A horizontal plane or plane refers to an X-Y plane. The top surface of a specific object means one surface positioned in a positive third direction with respect to the specific object, and the bottom surface of the specific object means one surface positioned in a negative third direction with respect to the specific object.

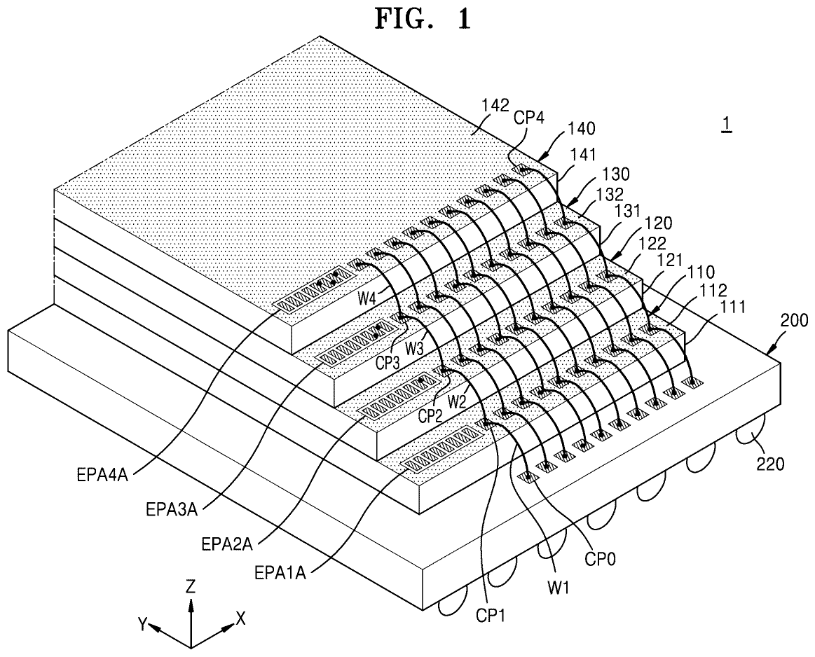

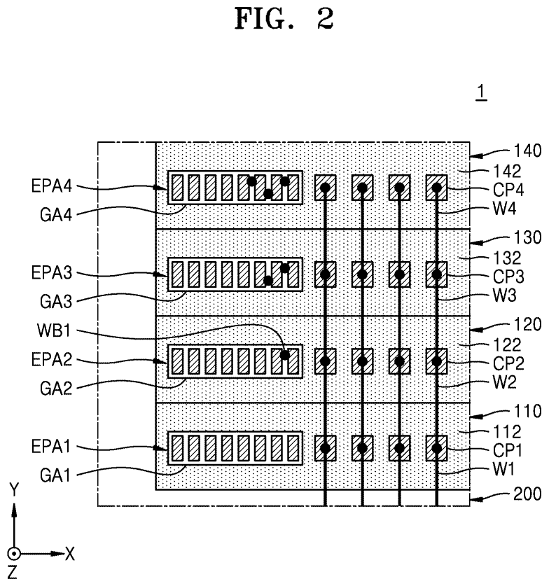

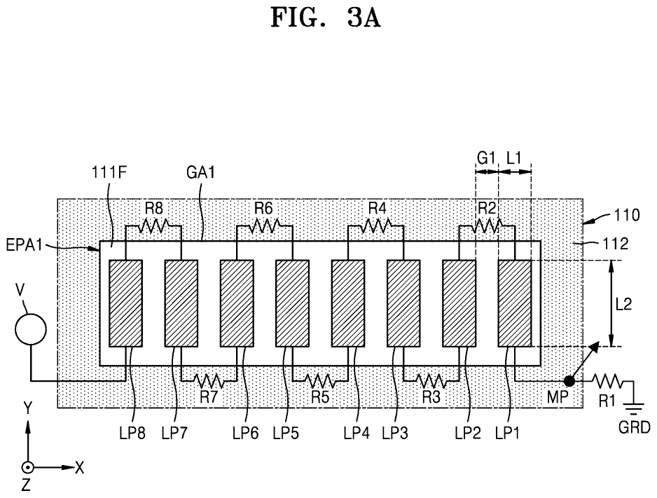

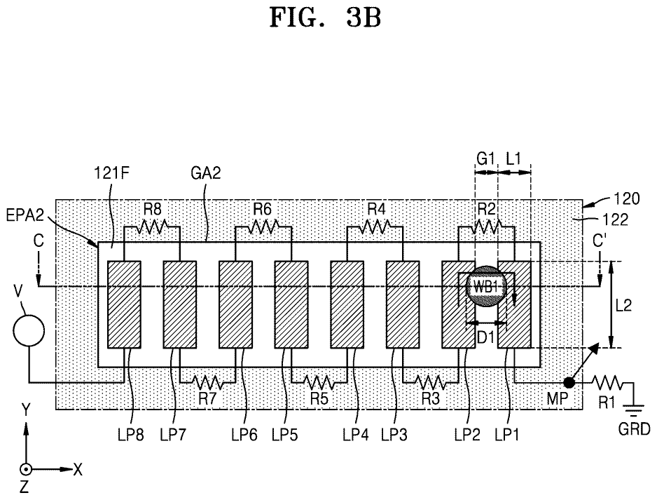

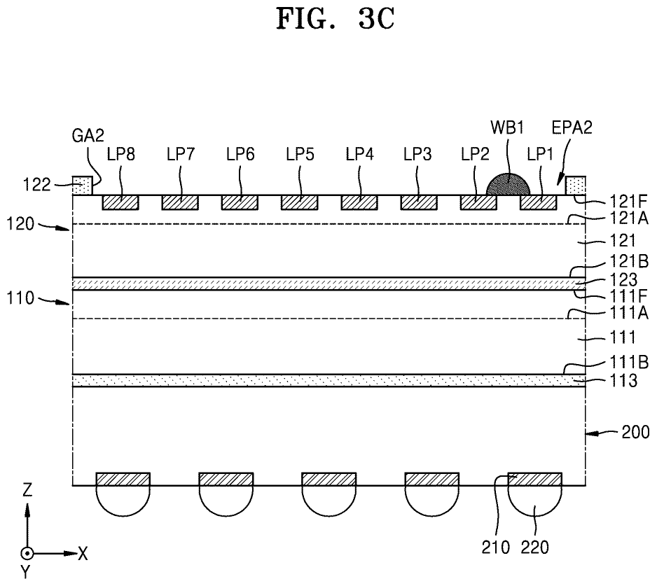

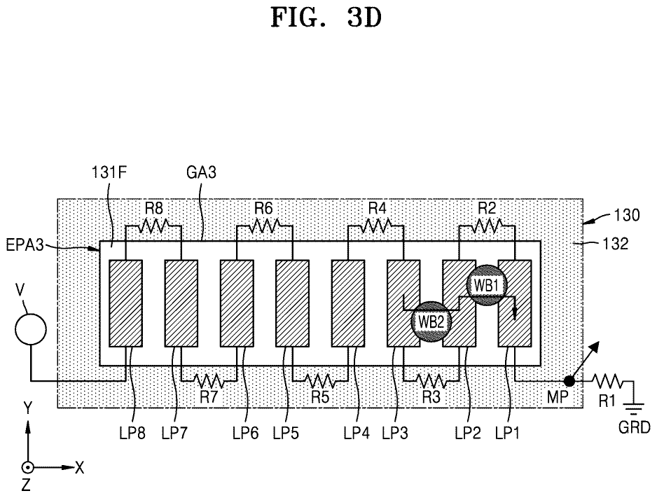

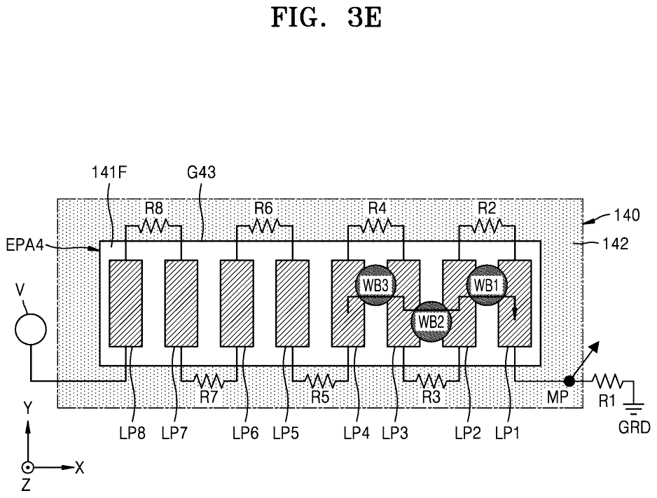

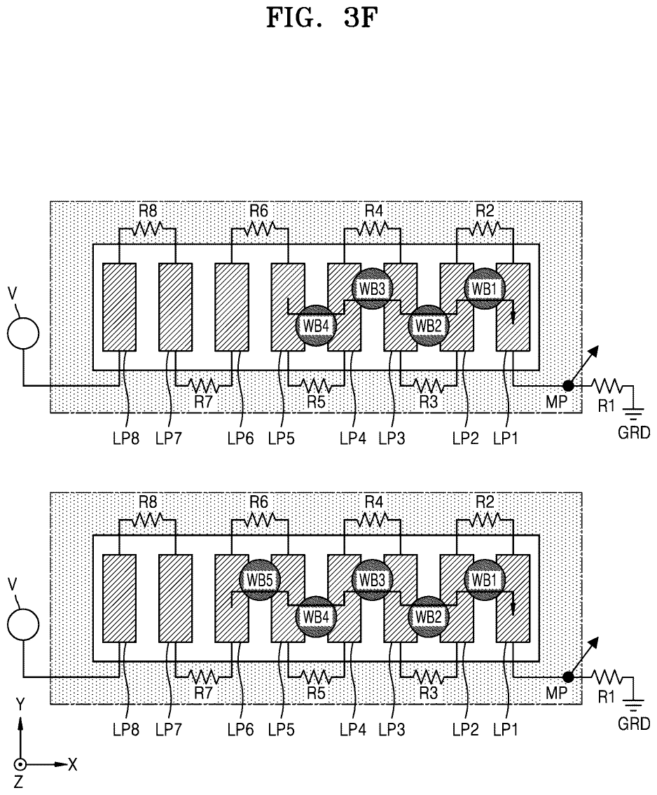

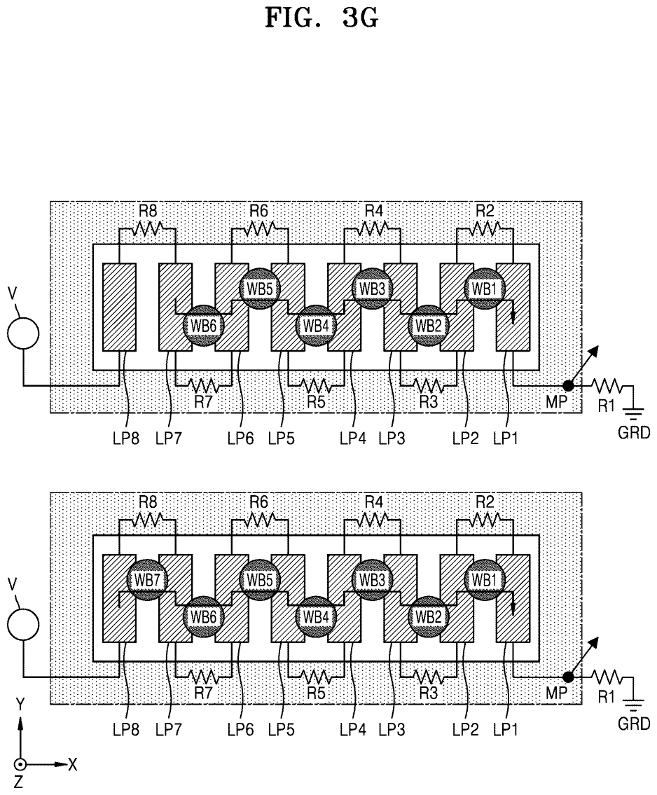

FIG. 1 is a perspective view showing a semiconductor package 1 according to embodiments. FIG. 2 is an enlarged plan view of a portion of a semiconductor package 1 according to embodiments. FIG. 3A is an enlarged plan view of a portion of a semiconductor package 1 according to embodiments. FIG. 3B is an enlarged plan view of a portion of a semiconductor package 1 according to embodiments. FIG. 3C is a cross-sectional view taken along line C-C′ of FIG. 3B. FIG. 3D is an enlarged plan view of a portion of a semiconductor package 1 according to embodiments. FIG. 3E is an enlarged plan view of a portion of a semiconductor package 1 according to embodiments.

Referring to FIGS. 1, 2, and 3A to 3E, a semiconductor package 1 according to embodiments may include a package substrate 200, a first semiconductor chip 110, a second semiconductor chip 120, a third semiconductor chip 130, and a fourth semiconductor chip 140.

The first semiconductor chip 110 may be provided on a top surface of the package substrate 200. The second semiconductor chip 120 may be arranged on the first semiconductor chip 110. Likewise, the third semiconductor chip 130 may be arranged on the second semiconductor chip 120, and the fourth semiconductor chip 140 may be arranged on the third semiconductor chip 130.

The first to fourth semiconductor chips 110, 120, 130, and 140 may be laterally offset and sequentially stacked. The second semiconductor chip 120 may be laterally offset from the first semiconductor chip 110 and may be provided on the first semiconductor chip 110. For example, the second semiconductor chip 120 may be offset from the first semiconductor chip 110 in a positive second direction (+Y direction). Likewise, the third semiconductor chip 130 may be arranged on the second semiconductor chip 120, and the third semiconductor chip 130 may be laterally offset from the second semiconductor chip 120. The fourth semiconductor chip 140 may be arranged on the third semiconductor chip 130, and the fourth semiconductor chip 140 may be laterally offset from the third semiconductor chip 130.

The first semiconductor chip 110, the second semiconductor chip 120, the third semiconductor chip 130, and the fourth semiconductor chip 140 may be referred to as a semiconductor chip stack. The semiconductor chip stack may include a plurality of semiconductor chips stacked in a stepwise manner.

A plurality of substrate pads CP0 may be provided on a top surface of the package substrate 200. The plurality of substrate pads CP0 provided on the top surface of the package substrate 200 may be laterally spaced apart from the first semiconductor chip 110 and may be provided on the package substrate 200. For example, the plurality of substrate pads CP0 may be spaced apart from the first semiconductor chip 110 in a negative second direction (-Y direction) and may be provided on the package substrate 200. In this disclosure, separation in the first direction may mean separation in a positive first direction or a negative first direction, and separation in the second direction may mean separation in a positive second direction or a negative second direction.

A plurality of external connection pads 210 and a plurality of external connection terminals 220 provided on the plurality of external connection pads 210 shown in FIG. 3C may be included on a bottom surface of the package substrate 200. An external electronic device, for example, a printed circuit board or the like may be connected through the plurality of external connection terminals 220.

The package board 200 may be, for example, a printed circuit board (PCB) or a redistribution structure.

When the package substrate 200 is a printed circuit board, the package substrate 200 includes a base layer, and the base layer may be formed of a plurality of stacked sub-base layers. A top surface and a bottom surface of the base layer may be covered by a solder resist layer. The plurality of substrate pads CP0 and the plurality of external connection pads 210 may be exposed to the top surface and the bottom surface of the package substrate 200, respectively, without being covered by the solder resist layer.

In some embodiments, the base layer may include at least one material selected from phenol resin, epoxy resin, and polyimide. For example, the base layer may include at least one material selected from frame retardant 4 (FR4), tetrafunctional epoxy, polyphenylene ether, epoxy/polyphenylene oxide, bismaleimide triazine (BT), Thermount, Cyanate ester, polyimide and liquid crystal polymer.

When the package substrate 200 is a redistribution structure, the package substrate 200 may include a plurality of redistribution insulating layers and a redistribution pattern provided in the redistribution insulating layer. The redistribution pattern may include a plurality of redistribution line patterns and a plurality of redistribution via patterns. The plurality of redistribution line patterns may be arranged between the plurality of redistribution insulating layers, and the plurality of redistribution via patterns may penetrate the redistribution insulating layers to be connected to the plurality of redistribution line patterns.

In some embodiments, the redistribution insulating layers may include an insulating material, for example, a photoimageable insulating (PID) resin. In this case, the redistribution insulating layers may further include an inorganic filler. The redistribution pattern may include a conductive material, for example, Cu, Al, Ag, Sn, Au, Ni, Pb, Ti, or an alloy thereof.

A plurality of first chip pads CP1 and a first identification pad array EPA1 may be provided on a top surface of the first semiconductor chip 110. The plurality of first chip pads CP1 and the first identification pad array EPA1 may be provided on the top surface of the first semiconductor chip 110 exposed due to the offset of the second semiconductor chip 120. That is, the plurality of first chip pads CP1 and the first identification pad array EPA1 may each be positioned on the top surface of the exposed first semiconductor chip 110 of the semiconductor chip stack stacked in a stepwise manner.

Each of the plurality of first chip pads CP1 and the first identification pad array EPA1 may be exposed from a first passivation layer 112 provided on the top surface of the first semiconductor chip 110. The first passivation layer 112 may be provided on the top surface of the first semiconductor chip 110, and at least a portion of the first passivation layer 112 may be arranged between the first semiconductor chip 110 and the second semiconductor chip 120.

A plurality of second chip pads CP2 and a second identification pad array EPA2 may be provided on a top surface of the second semiconductor chip 120. The plurality of second chip pads CP2 and the second identification pad array EPA2 may be provided on the top surface of the second semiconductor chip 120 exposed due to the offset of the third semiconductor chip 130. That is, the plurality of second chip pads CP2 and the second identification pad array EPA2 may each be positioned on the top surface of the exposed second semiconductor chip 120 of the semiconductor chip stack stacked in a stepwise manner.

Each of the plurality of second chip pads CP2 and the second identification pad array EPA2 may be exposed from a second passivation layer 122 provided on the top surface of the second semiconductor chip 120. The second passivation layer 122 may be provided on the top surface of the second semiconductor chip 120, and at least a portion of the second passivation layer 122 may be arranged between the second semiconductor chip 120 and the third semiconductor chip 130.

A plurality of third chip pads CP3 and a third identification pad array EPA3 may be provided on a top surface of the third semiconductor chip 130. The plurality of third chip pads CP3 and the third identification pad array EPA3 may be provided on the top surface of the third semiconductor chip 130 exposed due to the offset of the fourth semiconductor chip 140. That is, the plurality of third chip pads CP3 and the third identification pad array EPA3 may each be positioned on the top surface of the exposed third semiconductor chip 130 of the semiconductor chip stack stacked in a stepwise manner.

Each of the plurality of third chip pads CP3 and the third identification pad array EPA3 may be exposed from a third passivation layer 132 provided on the top surface of the third semiconductor chip 130. The third passivation layer 132 may be provided on the top surface of the third semiconductor chip 130, and at least a portion of the third passivation layer 132 may be arranged between the third semiconductor chip 130 and the fourth semiconductor chip 140.

A plurality of fourth chip pads CP4 and a fourth identification pad array EPA4 may be provided on a top surface of the fourth semiconductor chip 140. The plurality of fourth chip pads CP4 and the fourth identification pad array EPA4 may be provided on a portion adjacent to the outer edge of the top surface of the fourth semiconductor chip 140.

Each of the plurality of fourth chip pads CP4 and the fourth identification pad array EPA4 may be exposed from a fourth passivation layer 142 provided on the top surface of the fourth semiconductor chip 140. The fourth passivation layer 142 may be provided on the top surface of the fourth semiconductor chip 140.

In the disclosure, the semiconductor chip stack includes four, that is, first to fourth semiconductor chips 110, 120, 130, and 140 as examples, but embodiments are not limited thereto, and the semiconductor chip stack in some embodiments may include one or more semiconductor chips.

At least a portion of each of the plurality of substrate pads CP0, at least a portion of each of the plurality of first chip pads CP1, at least a portion of each of the plurality of second chip pads CP2, at least a portion of each of the plurality of third chip pads CP3, and at least a portion of each of the plurality of fourth chip pads CP4 may be electrically connected by conductive wires.

For example, at least a portion of each of the plurality of substrate pads CP0 and at least a portion of each of the plurality of the first chip pads CP1 corresponding to the plurality of substrate pads CP0 may be electrically connected to each other by a plurality of first conductive wires W1, respectively. At least a portion of each of the plurality of first chip pads CP1 and at least a portion of each of the plurality of the second chip pads CP2 corresponding to the plurality of first chip pads CP1 may be electrically connected to each other by a plurality of second conductive wires W2, respectively. At least a portion of each of the plurality of second chip pads CP2 and at least a portion of each of the plurality of the third chip pads CP3 corresponding to the plurality of second chip pads CP2 may be electrically connected to each other by a plurality of third conductive wires W3, respectively. At least a portion of each of the plurality of third chip pads CP3 and at least a portion of each of the plurality of the fourth chip pads CP4 corresponding to the plurality of third chip pads CP3 may be electrically connected to each other by a plurality of fourth conductive wires W4, respectively.

The first semiconductor chip 110 may include a first semiconductor substrate 111. The first semiconductor substrate 111 may include, for example, silicon (Si). Alternatively, the first semiconductor substrate 111 may include semiconductor elements, such as germanium (Ge), or compound semiconductors, such as silicon carbide (SiC), gallium arsenide (GaAs), indium arsenide (InAs), and indium phosphate (InP).

The first semiconductor substrate 111 may have a silicon-on-insulator (SOI) structure. For example, the first semiconductor substrate 111 may include a buried oxide (BOX) layer. The first semiconductor substrate 111 may include a conductive region, for example, a well doped with impurities. The first semiconductor substrate 111 may have various device isolation structures such as a shallow trench isolation (STI) structure.

As shown in FIG. 3C, the first semiconductor substrate 111 may have a first active surface 111A adjacent to a first top surface 111F of the first semiconductor chip 110 and a first inactive surface 111B opposite to the first active surface 111A, that is, corresponding to a bottom surface of the first semiconductor chip 110. The first inactive surface 111B may be referred to as a rear surface of the first substrate.

In the first semiconductor chip 110, a semiconductor device including a plurality of individual devices of various types may be formed on the first active surface 111A. The plurality of individual devices may include various microelectronic devices, for example, metal-oxide-semiconductor field effect transistors (MOSFET) such as complementary metal-insulator-semiconductor (CMOS) transistor, floating gate transistors, system large scale integration (LSI), micro-electro-mechanical systems (MEMS), active devices, passive devices, etc.

The plurality of individual devices may be electrically connected to the conductive region of the first semiconductor substrate 111. In addition, each of the plurality of individual devices may be electrically separated from other neighboring individual devices by an insulating film.

For example, the first semiconductor chip 110 may be a memory semiconductor chip, and the memory semiconductor chip may include a memory semiconductor device. In some embodiments, the memory semiconductor device may be a nonvolatile memory semiconductor device, such as flash memory, phase-change random access memory (PRAM), magnetoresistive random access memory (MRAM), ferroelectric random access memory (FeRAM), or resistive random access memory (RRAM). The flash memory may be, for example, a V-NAND flash memory. In some other embodiments, the memory semiconductor device may be a volatile memory semiconductor chip, such as dynamic random access memory (DRAM) or static random access memory (SRAM).

As shown in FIG. 3C, the second semiconductor substrate 121 may have a second active surface 121A adjacent to a second top surface 121F of the second semiconductor chip 120 and a second inactive surface 121B opposite to the second active surface 121A, that is, corresponding to a bottom surface of the second semiconductor chip 120. The second inactive surface 121B may be referred to as a rear surface of the second substrate.

The second semiconductor substrate 121 may include, for example, silicon. In the second semiconductor chip 120, a semiconductor device including a plurality of individual devices of various types may be formed on the second active surface 121A. The second semiconductor chip 120 may be a memory semiconductor chip, and the memory semiconductor chip may include a memory semiconductor device.

The description of the first semiconductor substrate 111 included in the first semiconductor chip 110 and the second semiconductor substrate 121 included in the second semiconductor chip 120 may be applied likewise to the third semiconductor chip 130 and the fourth semiconductor chip 140.

The first semiconductor chip 110 may be provided with a first adhesive film 113 on a bottom surface thereof and may be attached to a lower structure thereof by the first adhesive film 113. For example, the first adhesive film 113 may be provided on the bottom surface of the first semiconductor chip 110, and the first semiconductor chip 110 may be attached to the package substrate 200 by the first adhesive film 113.

The first adhesive film 113 may include a non-conductive film (NCF) or a non-conductive paste (NCP). A second adhesive film 123, a third adhesive film, and a fourth adhesive film may be provided on a bottom surface of the second semiconductor chip 120, a bottom surface of the third semiconductor chip 130, and a bottom surface of the fourth semiconductor chip 140, respectively. The second adhesive film 123 may provide adhesion between the first semiconductor chip 110 and the second semiconductor chip 120, the third adhesive film may provide adhesion between the second semiconductor chip 120 and the third semiconductor chip 130, and the fourth adhesive film may provide adhesion between the third semiconductor chip 130 and the fourth semiconductor chip 140.

Referring to FIG. 3A, the first identification pad array EPA1 may include a first identification pad group. For example, the first identification pad array EPA1 may include eight, that is, first to eighth identification pads LP1, LP2, LP3, LP4, LP5, LP6, LP7, and LP8. In the disclosure, the plurality of first identification pad groups may collectively refer to eight, that is, the first to eighth identification pads LP1, LP2, LP3, LP4, LP5, LP6, LP7, and LP8 included in the first identification pad array EPA1. In the disclosure, the case where the first to fourth identification pad arrays EPA1, EPA2, EPA3, and EPA4 each include eight identification pads is described as an example, but embodiments are not limited by the number of the first identification pad groups.

The first identification pad group may be a kind of active pad. The active pad may be referred to as chip enable (CE#), output enable (OE#), write enable (WE#) or the like in a circuit diagram or a data sheet. The first identification pad group of the first identification pad array EPA1 may distinguish the first to fourth semiconductor chips 110, 120, 130, and 140, may operate each of the semiconductor chips simultaneously or selectively, and may serve to distinguish and activate or deactivate each of the semiconductor chips.

In conventional semiconductor chips, according to chip enable (CE) reduction technology, the corresponding semiconductor chip may be activated or deactivated through electrical signals introduced into one or more enable pads. For example, signals flowing in through the plurality of active pads are distinguished by a turn-on/turn-off (ON/OFF), and the active signals may be distinguished by generating eight combinations for a total of three active pads. Through the active pad signal, the internal circuit provided in the semiconductor chip corresponding to the signal of the active pad is controlled to be operated, and the semiconductor chips corresponding to the inactivation state of the signal of the active pad are controlled to be in a standby state. This may be for the purpose of controlling a plurality of semiconductor chips, managing power efficiency, and preventing a signal collision.

However, in the semiconductor package 1 according to embodiments, the voltage of the power source V input to the first identification pad group may remain constant, and the synthesis resistance of the first identification pad group may vary. As the synthesis resistance of the first identification pad group is changed, the magnitude of the voltage applied across the first resistor R1, that is, the value of the voltage measured at the measurement point MP, may be changed, and the semiconductor chips included in the stacked semiconductor chip stack included in the semiconductor package 1 may be identified through the magnitude of the voltage measured at the measurement point MP. In this disclosure, the first resistor R1 may be referred to as a reference resistor.

When the identified semiconductor chip matches a target semiconductor chip corresponding to a signal input through a plurality of chip pads rather than a plurality of identification pads, the corresponding semiconductor chip may be activated. Details of a structure of identifying a semiconductor chip in the semiconductor package 1 according to embodiments will be described later.

The first identification pad group may be exposed upward from the first passivation layer 112. For example, a first area GA1 may be located in a portion of the first passivation layer 112. The first area GA1 may mean a portion where a first upper surface 111F of the first semiconductor chip 110 in which the first passivation layer 112 is not provided is exposed. The first area GA1 may not be covered by the first passivation layer 112. The first identification pad group may be located in the first area GA1. The first area GA1 may be an area in which the first identification pad group and portions of the first upper surface 111F are included. The circumference of the first area GA1 may be surrounded by the first passivation layer 112 when viewed in a plan view.

The first identification pad group may be provided in the first area GA1. The identification pads in the first identification pad group may be arranged to be spaced apart from each other in one direction. For example, the identification pads in the first identification pad group may be laterally spaced apart from each other and may be provided on the top surface of the first semiconductor chip 110. The identification pads in the first identification pad group may be spaced apart from each other at a predetermined interval. The identification pads in the first identification pad group may be aligned with each other in one direction, and for example, the first identification pad group may be arranged in a first direction (+X direction).

The first to eighth identification pads LP1, LP2, LP3, LP4, LP5, LP6, LP7, and LP8 included in the first identification pad group may have the same size. When viewed in a plan view, the first identification pad LP1 may have a rectangular shape having a longer side in one direction. For example, from a plan view, the shape of the first identification pad LP1 may be a rectangular shape having a long length in a second direction, and the first identification pad group may be aligned in the first direction perpendicular to the second direction. The second to eighth identification pads LP2, LP3, LP4, LP5, LP6, LP7, and LP8 may each have a rectangular shape having a longer side in one direction when viewed in a plan view.

A first length L1 that is the length of the first identification pad LP1 in the first direction may be shorter than a second length L2 that is the length of the first identification pad LP1 in the second direction. The second identification pad LP2 may be spaced laterally apart from the first identification pad LP1. For example, if the direction of the second length L2 of the first identification pad LP1 is the second direction, the second identification pad LP2 may be spaced apart from the first identification pad LP1 in the first direction. A first gap G1, which is a distance spaced between the first identification pad LP1 and the second identification pad LP2, may be less than the first length L1, for example. Alternatively, the first gap G1 may be less than the second length L2.

The first gap G1 may be less than a first diameter D1, which is a diameter of a first wire ball WB1 to be described later in FIG. 3B. A sum of the first gap G1 and two times the first length L1 may be greater than the diameter of the first wire ball WB1. According to this size relationship, the size of the first wire ball WB1 is required to be less than the size of the sum of both the first identification pads LP1 and the second identification pad LP2. Alternatively, the sum of the first gap G1 and the first length L1 may be greater than the diameter of the first wire ball WB1. The size relationship may be required for each of a plurality of wire balls to be arranged on the first identification pad group, as shown in FIGS. 3D to 3G to be described later.

The first length L1, which is the length of the first identification pad LP1 in the first direction, may be shorter than the length of each of the plurality of first chip pads CP1 provided in the first semiconductor chip 110. Alternatively, the first length L1, which is the length of the first identification pad LP1 in the first direction, may be shorter than the length of each of the plurality of first chip pads CP1 provided in the first semiconductor chip 110 in the first direction and the length of each of the plurality of first chip pads CP1 in the second direction.

The length of each of the plurality of first chip pads CP1 in the first direction and the length of each of the plurality of first chip pads CP1 in the second direction need to be more than the size of a wire ball in order to stably bond the wire ball, which is a contact of the conductive wire. However, since the identification pads of the first identification pad group do not have a wire ball arranged therein, the first identification pad LP1 may have a first length L1 less than the size of each of the plurality of first chip pads CP1. Therefore, an area occupied by the identification pads according to embodiments may be smaller than an area occupied by the same number of first identification pads LP1. For example, the area occupied by the four first chip pads CP1 and the area occupied by the eight identification pads may be the same, or the area occupied by the eight identification pads may be smaller than the area occupied by the four first chip pads CP1.

The first identification pad LP1 may be spaced apart from the adjacent first passivation layer 112. Alternatively, in some other embodiments, a portion of the first identification pad LP1 may be covered by the first passivation layer 112. The eighth identification pad LP8 may be spaced apart from the adjacent first passivation layer 112. Alternatively, in some other embodiments, a portion of the eighth identification pad LP8 may be covered by the first passivation layer 112.

A resistor may be electrically connected between every two adjacent identification pads of the identification pads of the first identification pad group. For example, a second resistor R2 may be electrically connected between the first identification pad LP1 and the second identification pad LP2. The second resistor R2 may be embedded in the first semiconductor chip 110. The second resistor R2 may include one or more resistors.

A third resistor R3, a fourth resistor R4, and a fifth resistor R5 may be provided between the second identification pad LP2 and the third identification pad LP3, between the third identification pad LP3 and the fourth identification pad LP4, and between the fourth identification pad LP4 and the fifth identification pad LP5, respectively. A sixth resistor R6, a seventh resistor R7, and an eighth resistor R8 may be provided between the fifth identification pad LP5 and the sixth identification pad LP6, between the sixth identification pad LP6 and the seventh identification pad LP7, and between the seventh identification pad LP7 and the eighth identification pad LP8, respectively. Likewise, the third to eighth resistors R3, R4, R5, R6, R7, and R8 may be embedded in the first semiconductor chip 110, and each of them may include one or more resistors.

The identification pads of the first identification pad group may be connected to each other in series. As described above, the plurality of identification pads included in the first identification pad group are electrically connected to each other with a resistor therebetween. One end of the first identification pad group may be connected to the power source V, and the other end thereof may be connected to the ground GND. The power source V may supply the same voltage to all semiconductor chips provided in the semiconductor package 1.

For example, the eighth identification pad LP8 may be connected to the power source V, and the first identification pad LP1 may be connected to the ground GND. The power source V connected to the eighth identification pad LP8 may be electrically connected to, for example, a VCCQ, VDDQ, or VCCIO power source connected to the first semiconductor chip 110. The power source V connected to the eighth identification pad LP8 may have, for example, a voltage of 1.8 V, 2.5 V, or 3.3 V. For example, the ground GND connected to the first identification pad LP1 may be electrically connected to a voltage source substrate VSS connected to the first semiconductor chip 110.

A first resistor R1 and a measurement point MP may be provided between the first identification pad LP1 and the ground GND. The first resistor R1 may be embedded in the first semiconductor chip 110, and the first resistor R1 may include one or more resistors. The measurement point MP may be embedded in the first semiconductor chip 110 to measure the magnitude of a voltage applied across the first resistor R1.

In the case of FIG. 3A, for example, when the first to eighth resistors R1, R2, R3, R4, R5, R6, R7, and R8 have the same resistance and a voltage of 1.8V is input through the power source V, the voltage applied to the first resistor R1 may be 0.225 V. In the disclosure, the second to eighth resistors R2, R3, R4, R5, R6, R7, and R8 may be collectively referred to as a plurality of identification resistors. As described above, the first resistor R1 may be referred to as a reference resistor.

The magnitude of the voltage applied across the first resistor R1 may be measured by an electrical circuit branched from and connected to the measurement point MP, and the semiconductor chip may be identified according to the magnitude of the measured voltage. For example, when the magnitude of the voltage falls within a range of about 0.2 V to about 0.25 V, the semiconductor chip may be identified as the first semiconductor chip 110. As described above, when the magnitude of the voltage applied across the first resistor R1 is about 0.225 V, the voltage measured at the measurement point MP falls within a range of about 0.2 V to about 0.25 V, and thus may be identified as the first semiconductor chip 110.

In FIGS. 3B to 3G, a voltage applied across the first resistor R1 depending on the synthesis resistance will be described. Descriptions that are not separately given may be substantially the same as those described above.

Referring to FIG. 3B, the second identification pad array EPA2 may include a second identification pad group. For example, the second identification pad array EPA2 may include eight, that is, first to eighth identification pads LP1, LP2, LP3, LP4, LP5, LP6, LP7, and LP8.

The second identification pad group may be exposed upward from the second passivation layer 122. For example, a second area GA2 may be located in a portion of the second passivation layer 122. The second area GA2 may mean a portion where a second upper surface 121F of the second semiconductor chip 120 in which the second passivation layer 122 is not provided is exposed.

The second area GA2 may not be covered by the second passivation layer 122. The second identification pad group may be located in the second area GA2. The second area GA2 may be an area in which the second identification pad group and portions of the second upper surface 121F are included. The circumference of the second area GA2 may be surrounded by the second passivation layer 122 when viewed in a plan view. The second identification pad group may be provided in the second area GA2. The identification pads in the second identification pad group may be spaced apart from each other in one direction.

A first wire ball WB1 may be provided on some portions of the second identification pad group. For example, the first wire ball WB1 may be provided on the first identification pad LP1 and the second identification pad LP2. The first wire ball WB1 may be a contact generated when a conductive wire is attached to a pad, just as generated when the first conductive wire W1 is attached to the first chip pad CP1. The first wire ball WB1 may be in contact with the second top surface 121F. That is, the first wire ball WB1 may be in contact with the first identification pad LP1, the second top surface 121F, and the second identification pad LP2.

One end of the first conductive wire W1 is attached to the first chip pad CP1, extends by a specific length, and then is cut so that the other end of the first conductive wire W1 is connected to another chip pad. Alternatively, after one end of the conductive wire is bonded to the first identification pad LP1 and the second identification pat LP2, the conductive wire may be cut in a state in which the conductive wire hardly extends, to thereby form the first wire ball WB1. The first wire ball WB1 may be formed during a wire bonding process using a capillary. That is, the first wire ball WB1 may be formed together in the process of forming the first conductive wire W1.

A diameter of the first wire ball WB1 may be greater than a diameter of the first conductive wire W1. For example, a diameter of the cross section of the first conductive wire W1 may be in a range of about 20 μm to about 25 μm, and accordingly, a diameter of the first wire ball WB1 may be in a range of about 50 μm to about 70 μm.

In order to easily attach the wire ball, which is a contact of the first conductive wire W1, to the first chip pad CP1, the size of the first chip pad CP1 may be larger than the size of the wire ball attached to the first chip pad CP1. Likewise, the size of the first chip pad CP1 may be greater than the diameter of the first wire ball WB1 formed as a portion of the conductive wire. For example, the size based on one direction of the first chip pad CP1 may be in a range of about 55 μm to about 90 μm, or may be larger than this range.

The first diameter D1, which is the diameter of the first wire ball WB1, may be greater than the first gap G1. The size of the first gap G1 may be limited to a certain level in the process of forming the pad. For example, the size of the first gap G1 may be limited to less than about 25 μm. Alternatively, the size of the first gap G1 may be about 20 μm or more. The size of the first gap G1 may correspond to a range of about 20 μm to about 40 μm.

The first length L1 of the first identification pad LP1 may correspond to be in a range of about 50 μm to about 80 μm. The first length L1 of the first identification pad LP1 may be shorter than the length of the first chip pad CP1 in the first direction. The second length L2 of the first identification pad LP1 may correspond to be in a range of about 50 μm to about 200 μm. For example, the second length L2 may correspond to be in a range of 1.5 to 4 times the first length L1. Numerical examples of the first length L1 and the second length L2 do not limit embodiments.

The first diameter D1 may be less than the sum of the first gap G1 and two times the first length L1. This may be to prevent the size of the first wire ball WB1 from being excessively large compared to the gap in which the first identification pad LP1 and the second identification pad LP2 are located. The first diameter D1 may be greater than the sum of the first gap G1 and the first length L1. This may be to stably secure the electrical contact between the first wire ball WB1, the first identification pad LP1, and the second identification pad LP2.

The planar flat surface of the first wire ball WB1 may be generally close to a circular shape. When viewed in a plan view of the first wire ball WB1, the center of the circular shape may be positioned at a position where it is easy to secure electrical connection between the first wire ball WB1, the first identification pad LP1, and the second identification pad LP2. For example, the center of the circular shape from a plan view of the first wire ball WB1 may be arranged between the first identification pad LP1 and the second identification pad LP2.

The first wire ball WB1 may electrically connect the first identification pad LP1 with the second identification pad LP2. When power is connected to the second identification pad LP2, power may be supplied to the first identification pad LP1 through the second resistor R2 provided in the electrical wire connecting the first identification pad LP1 with the second identification pad LP2 as illustrated in FIG. 3A in which the first wire ball WB1 is not provided.

When the first wire ball WB1 is provided as shown in FIG. 3B, the resistance of the electrical path through the first wire ball WB1 may be significantly less than the resistance of the electrical path through the second resistor R2. The first wire ball WB1 is a portion of the conductive wire and may include a material having a very little specific resistance. For example, the first wire ball WB1 may include copper (Cu).

When an electrical path not passing through the second resistor R2 is formed by the first wire ball WB1, the electrical signal input from the power source V may pass through the plurality of identification resistors except for the second resistor R2. As shown in FIG. 3A, the magnitude of the voltage applied across the first resistor R1 may be increased as compared with the case where all of the plurality of identification resistors are passed. As the first wire ball WB1 is arranged, the magnitude of the voltage measured at the measurement point MP may increase. The semiconductor chip may be identified according to the voltage measured at the measurement point MP, and for example, the second semiconductor chip 120 may be identified by the arrangement of the first wire ball WB1 in FIG. 3B.

Referring to FIG. 3D, the third identification pad array EPA3 may include a third identification pad group. For example, the third identification pad array EPA3 may include eight, that is, first to eighth identification pads LP1, LP2, LP3, LP4, LP5, LP6, LP7, and LP8.

The third identification pad group may be exposed upward from the third passivation layer 132. For example, a third area GA3 may be located in a portion of the third passivation layer 132. The third area GA3 may mean a portion where a third upper surface 131F of the third semiconductor chip 130 in which the third passivation layer 132 is not provided is exposed.

A first wire ball WB1 and a second wire ball WB2 may be provided on some portions of the first identification pad group, respectively. For example, the first wire ball WB1 may be provided on the first identification pad LP1 and the second identification pad LP2, and the second wire ball WB2 may be provided on the second identification pad LP2 and the third identification pad LP3. The second wire ball WB2 may be a contact generated when a conductive wire is attached to a pad. The second wire ball WB2 may be in contact with the second identification pad LP2, the third top surface 131F, and the third identification pad LP3.

The first wire ball WB1 may be arranged on one side of the first identification pad LP1 and the second identification pad LP2, in a Y direction, and the second wire ball WB2 may be arranged on the other side of the second identification pad LP2 and the third identification pad LP3, in a-Y direction. In other words, the first wire ball WB1 and the second wire ball WB2 may be alternately arranged vertically so as not to contact each other.

The first wire ball WB1 and the second wire ball WB2 may electrically connect the first identification pad LP1, the second identification pad LP2, and the third identification pad LP3, with each other. When the first wire ball WB1 and the second wire ball WB2 are provided, the resistance of the electrical path through the first wire ball WB1 and the second wire ball WB2 may be significantly less than the resistance of the electrical path through which the second resistor R2 and the third resistor R3 are provided. The first wire ball WB1 and the second wire ball WB2 may include a material having a very little specific resistance as a portion of the conductive wire.

When an electrical path not passing through the second resistor R2 and the third resistor R3 is formed by the first wire ball WB1 and the second wire ball WB2, the electrical signal input from the power source V may pass through the plurality of identification resistors excluding the second resistor R2 and the third resistor R3. Compared to the case of FIG. 3B, the magnitude of the voltage applied across the first resistor R1 may be increased. As the first wire ball WB1 and the second wire ball WB2 are arranged, the magnitude of the voltage measured at the measurement point MP may increase. The semiconductor chip may be identified according to the voltage measured at the measurement point MP, and for example, the third semiconductor chip 130 may be identified by the arrangement of the first wire ball WB1 and the second wire ball WB2 in FIG. 3D.

The semiconductor package 1 may further include a controller (not shown). The controller may transmit and receive electrical data to and from a semiconductor chip. The controller may transmit and receive data including data capable of identifying a semiconductor chip in the electrical data. As described above, when a semiconductor chip is identified according to a voltage measured at the measurement point MP, and data capable of identifying a semiconductor chip included in the data transmitted and received to and from the controller is transmitted, the corresponding semiconductor chip may be controlled to process the data.

Referring to FIG. 3E, the fourth identification pad array EPA4 may include a fourth identification pad group. For example, the fourth identification pad array EPA4 may include eight, that is, first to eighth identification pads LP1, LP2, LP3, LP4, LP5, LP6, LP7, and LP8.

The fourth identification pad group may be exposed upward from the fourth passivation layer 142. For example, a fourth area GA4 may be located in a portion of the fourth passivation layer 142. A first wire ball WB1, a second wire ball WB2, and a third wire ball WB3 may be provided on some portions of the first identification pad group, respectively. For example, the first wire ball WB1 may be provided on the first identification pad LP1 and the second identification pad LP2, the second wire ball WB2 may be provided on the second identification pad LP2 and the third identification pad LP3, and the third wire ball WB3 may be provided on the third identification pad LP3 and the fourth identification pad LP4. The third wire ball WB3 may be a contact generated when a conductive wire is attached to a pad. The third wire ball WB3 may be in contact with the third identification pad LP3, the fourth top surface 141F, and the fourth identification pad LP4.

The first wire ball WB1, the second wire ball WB2, and the third wire ball WB3 may be alternately arranged on the fourth identification pad group so as not to be in contact with each other.

The first wire ball WB1, the second wire ball WB2, and the third wire ball WB3 may electrically connect the first identification pad LP1, the second identification pad LP2, the third identification pad LP3, and the fourth identification pad LP4, with each other. When the first wire ball WB1, the second wire ball WB2, and the third wire ball WB3 are provided, the resistance of the electrical path through the first wire ball WB1, the second wire ball WB2, and the third wire ball WB3 may be significantly less than the resistance of the electrical path through which the second resistor R2, the third resistor R3, and the fourth resistor R4 are provided.

When an electrical path not passing through the second resistor R2, the third resistor R3, and the fourth resistor R4 is formed by the first wire ball WB1, the second wire ball WB2, and the third wire ball WB3, the electrical signal input from the power source V may pass the plurality of identification resistors excluding the second resistor R2, the third resistor R3, and the fourth resistor R4. Compared to the case of FIG. 3C, the magnitude of the voltage applied across the first resistor R1 may be increased. As the first wire ball WB1, the second wire ball WB2, and the third wire ball WB3 are arranged, the magnitude of the voltage measured at the measurement point MP may be increased. The semiconductor chip may be identified according to the voltage measured at the measurement point MP, and for example, the fourth semiconductor chip 140 may be identified by the arrangement of the first wire ball WB1, the second wire ball WB2, and the third wire ball WB3 in FIG. 3E.

FIG. 3F is an enlarged plan view of a portion of a semiconductor package 1 according to embodiments. FIG. 3G is an enlarged plan view of a portion of a semiconductor package 1 according to embodiments.

Referring to FIGS. 3F and 3G, a fourth wire ball WB4 may be further arranged, or the fourth wire ball WB4 and a fifth wire ball WB5 may be further arranged, or the fourth wire ball WB4, the fifth wire ball WB5, and a sixth wire ball WB6 may be further arranged, or the fourth wire ball WB4, the fifth wire ball WB5, the sixth wire ball WB6, and a seventh wire ball WB7 may be further arranged. A case in which the fourth wire ball WB4 is further arranged and a case in which the fourth wire ball WB4 and the fifth wire ball WB5 are further arranged, are shown in FIG. 3F, and a case in which the fourth wire ball WB4, the fifth wire ball WB5, and the sixth wire ball WB6 are further arranged and a case in which the fourth wire ball WB4, the fifth wire ball WB5, the sixth wire ball WB6, and the seventh wire ball WB7 are further arranged, are shown in FIG. 3G.

The fourth wire ball WB4 may be arranged on the fourth identification pad LP4 and the fifth identification pad LP5. When the first to fourth wire balls WB1, WB2, WB3, and WB4 are arranged, electric current may pass through the first to fourth wire balls WB1, WB2, WB3, and WB4 without passing through the second to fifth resistors R2, R3, R4, and R5. Therefore, the synthesis resistance is reduced compared to the case where the first to third wire balls WB1, WB2, and WB3 are arranged, and the voltage applied across the first resistance R1 may be greater when four wire balls are arranged than when the three wire balls are arranged. Therefore, the semiconductor chip may be identified by the arrangement of the first to fourth wire balls WB1, WB2, WB3, and WB4 as shown in FIG. 3F.

By applying the principle described above, even when the fifth wire ball WB5, the sixth wire ball WB6, and the seventh wire ball WB7 are respectively further arranged, the voltage applied across the first resistor R1 may also further increase as more wire balls are added. As the number of arranged wire balls increases, the voltage applied across the first resistor R1 increases, and the semiconductor chip may be identified by measuring the voltage applied across the first resistor R1 at the measurement point MP.

According to embodiments, the arrangement of the one or more wire balls may be arranged in the order in which a plurality of identification pads are electrically connected. For example, as shown in FIGS. 3A to 3G, the first identification pad LP1 to the eighth identification pad LP8 are electrically connected in series, and the arrangement of one or more wire balls may be sequentially arranged according to the number of wire balls, starting with the arrangement between the first identification pad LP1 and the second identification pad LP2 ending with the arrangement between the seventh identification pad LP7 and the eighth identification pad LP8.

The plurality of identification pads illustrated in FIGS. 3A to 3G include eight identification pads, and a total of seven wire balls may be arranged between respective two adjacent identification pads. The number of methods of arranging wire balls is a total of eight, within the method of arranging the wire balls in order, including the case where wire balls are not arranged. Accordingly, when seven wire balls are provided in the plurality of identification pads, a total of eight semiconductor chips may be identified.

In the semiconductor package 1 according to embodiments, a semiconductor chip may be identified by a difference in voltage levels generated by wire balls arranged on the plurality of identification pads. The plurality of identification pads may have sizes smaller than chip pads provided on a semiconductor chip. In identifying a plurality of semiconductor chips, a plurality of identification pads having a small size in a relatively small space may be arranged, and wire balls may be formed on a plurality of identification pads in an existing wire bonding process of a conductive wire in the plurality of identification pads. An area in which identification pads required for identification of a semiconductor chip are provided may be reduced, and wire balls may be arranged using an existing process at the same time. Therefore, the overall size of the semiconductor package may be reduced through efficient space arrangement of identification pads in the semiconductor package 1 according to embodiments, and multiple semiconductor chips may be identified.

In some embodiments, two or more identification pad arrays may be provided per semiconductor chip. For example, two identification pad arrays in which four identification pads are provided may be provided in semiconductor chips. Since the two identification pad arrays may generate four voltage level differences each, a total of 16 semiconductor chips may be identified. Alternatively, in some embodiments, two identification pad arrays in which eight identification pads are provided may be provided in semiconductor chips. Since the two identification pad arrays may generate a total of eight voltage level differences, a total of 64 semiconductor chips may be identified.

In some embodiments, the identification pad array may be provided between a semiconductor chip and another semiconductor chip. The identification pad array may be provided in a space where a semiconductor chip and another semiconductor chip are attached and stacked, and wire balls may be arranged in the identification pad array before being stacked on the semiconductor chip, and then a stacking process of semiconductor chips may be performed. In the case of such an embodiment, the space of the semiconductor chip may be configured more efficiently.

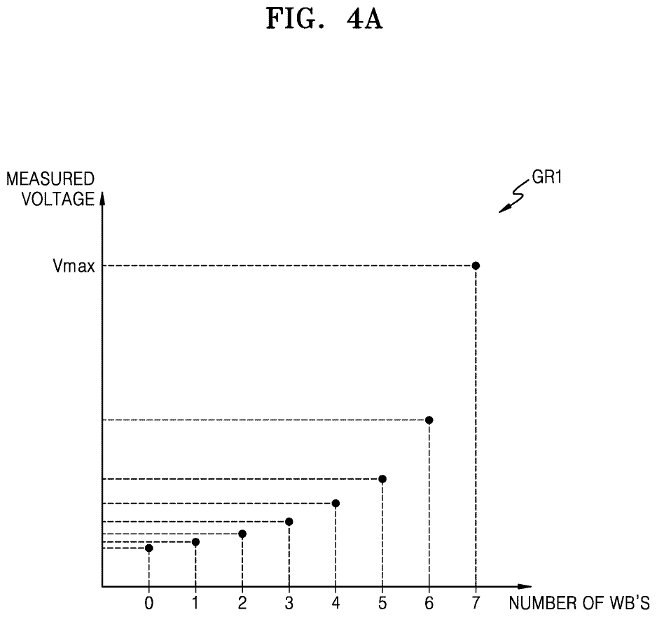

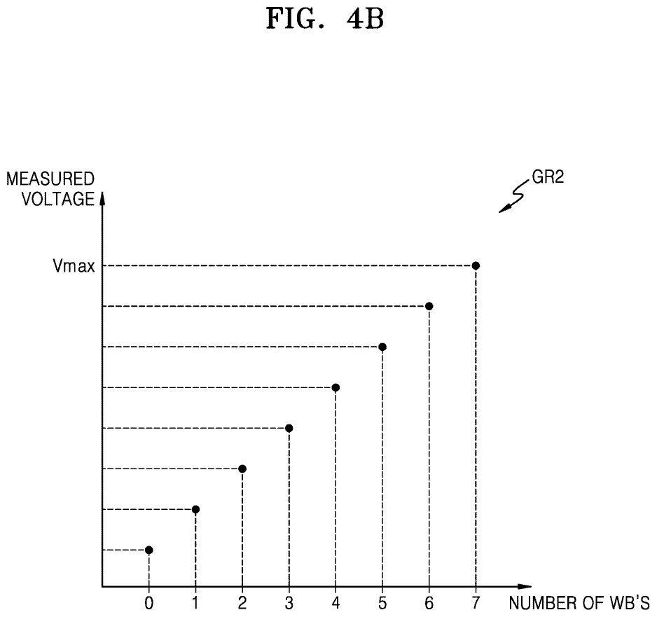

FIG. 4A is a graph illustrating a relative value of a voltage level that may be measured at a measurement point MP of a semiconductor package 1 according to embodiments. FIG. 4B is a graph illustrating a relative value of a voltage level that may be measured at a measurement point MP of a semiconductor package 1 according to embodiments.

Referring to FIG. 4A, when each of the plurality of identification resistors described above has the same magnitude, the voltage magnitude may be measured at the measurement point MP as shown in the first graph GR1. For example, as described above in FIGS. 1 to 3G, when eight identification pads are provided and 0 to 7 wire balls are arranged, the measured voltage when 7 wire balls are arranged may be Vmax.

One-half of Vmax may be measured at the measurement point MP when six wire balls are placed, one-third of Vmax may be measured at the measurement point MP when five wire balls are placed, one-quarter of Vmax may be measured at the measurement point MP when four wire balls are placed, one-fifth of Vmax may be measured at the measurement point MP when three wire balls are placed, one-sixth of Vmax may be measured at the measurement point MP when two wire balls are placed, one-seventh of Vmax may be measured at the measurement point MP when one wire ball is placed, and one-eighth of Vmax may be measured at the measurement point MP when no wire balls are placed. The first graph GR1 is a graph showing the relative voltage level measured according to the number of wire balls based on Vmax.

The voltage measured at the measurement point MP may vary according to the resistance value of each of a plurality of identification resistors and the arrangement of wire balls in the semiconductor chip, and accordingly, the voltage range identified in the semiconductor chip may be set differently to identify the semiconductor chip.

Referring to FIG. 4B, values of a plurality of identification resistors may be appropriately set so that the magnitude of the voltage measured at the measurement point MP is measured at equal intervals. For example, as the number of wire balls increases, as shown in the second graph GR2, the values of the plurality of identification resistors may be set so that the relative magnitude of the measured voltage increases at regular intervals.

Referring to FIG. 4B together with FIG. 3A, for example, the resistance value of the first resistor R1 may be assumed to be 1. The second resistor R2 may be configured to be 4, the third resistor R3 may be configured to be 4/3, the fourth resistor R4 may be configured to be ⅔, the fifth resistor R5 may be configured to be ⅖, the sixth resistor R6 may be configured to be 4/15, the seventh resistor R7 may be configured to be 4/21, and the eighth resistor R8 may be configured to be 1/7. When a total of eight wire balls are sequentially arranged as shown in FIGS. 3A to 3G by setting values of a plurality of identification resistors as described above, a voltage of which the magnitude is uniformly increased according to the number of wire balls may be measured as shown in the second graph GR2. Compared to the case of the first graph GR1 of FIG. 4A, in the case of the second graph GR2, a gap between voltages may be secured, and thus it may be easier to identify the semiconductor chip through the voltage level in the semiconductor chip.

In FIG. 4B, it may be seen that the resistances of the resistors described in FIG. 4B are gradually reduced in the second to eighth resistors R2, R3, R4, R5, R6, R7 and R8, except for the first resistor R1. That is, when the wire balls are sequentially arranged in the order from the second identification pad LP2 to the eighth identification pad LP8, the gap between the measurement voltages may be secured at a certain level by arranging the values of the second resistance R2 to the eighth resistance R8 to gradually decrease. By securing the gap between the measurement voltages measured at the measurement point MP in the semiconductor chip at a certain level, it is possible to more easily identify the semiconductor chip.

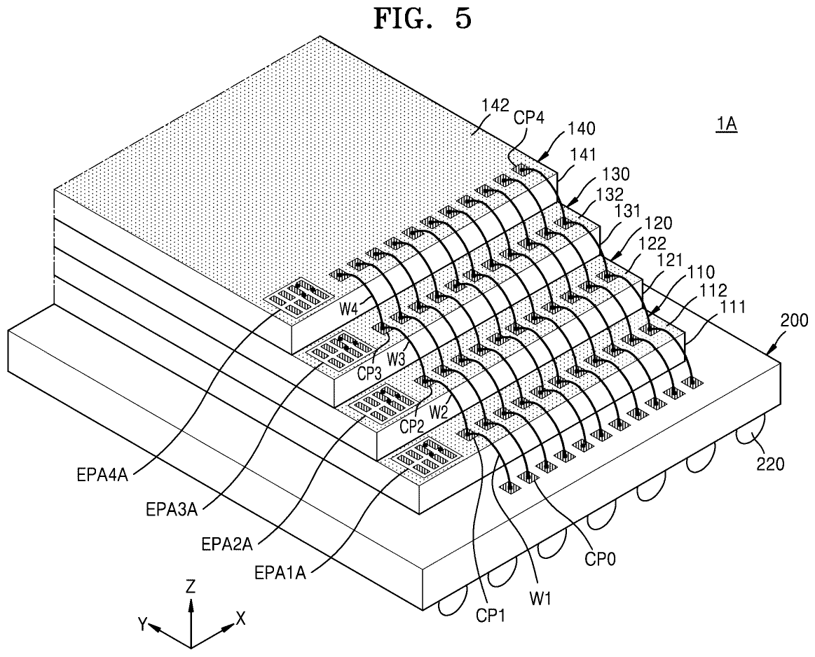

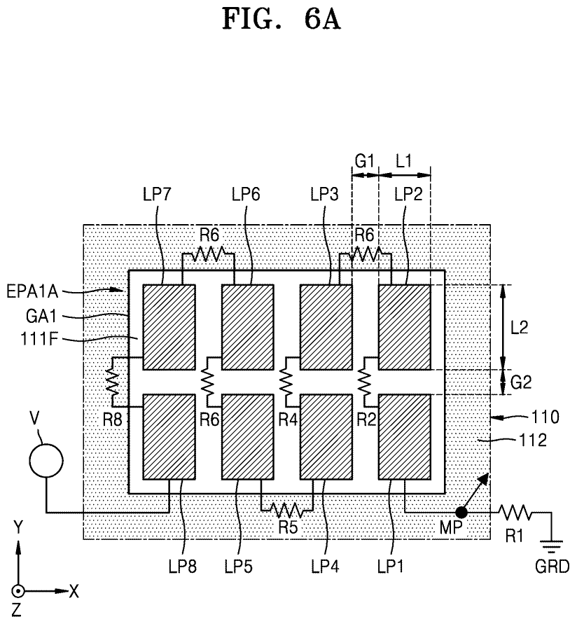

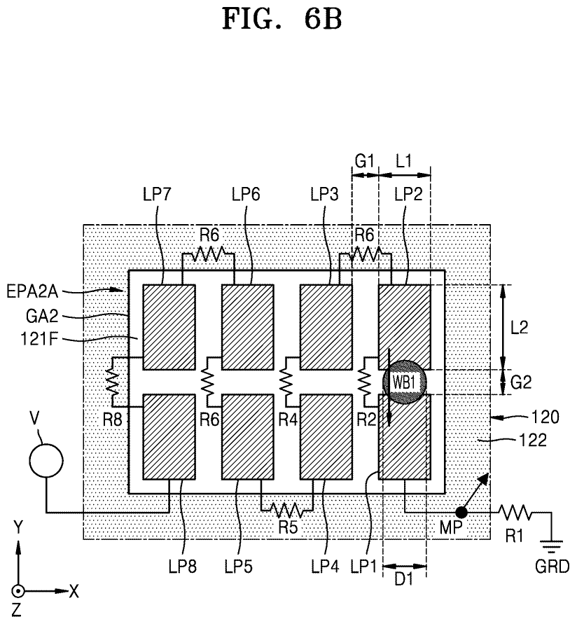

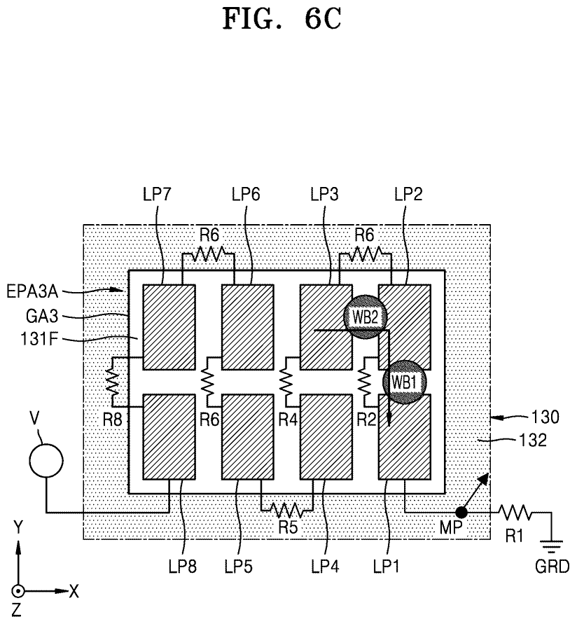

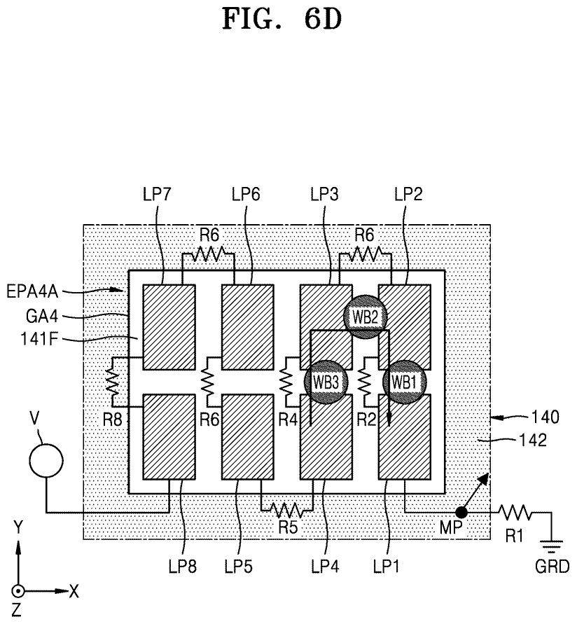

FIG. 5 is a perspective view showing a semiconductor package 1A according to embodiments. FIG. 6A is an enlarged plan view of a portion of a semiconductor package 1A according to embodiments. FIG. 6B is an enlarged plan view of a portion of a semiconductor package 1A according to embodiments. FIG. 6C is an enlarged plan view of a portion of a semiconductor package 1A according to embodiments. FIG. 6D is an enlarged plan view of a portion of a semiconductor package 1A according to embodiments. Hereinbelow, descriptions that are not separately given may be substantially the same as those described above.

Referring to FIGS. 5 and 6A to 6D, a semiconductor package 1A according to embodiments may include a package substrate 200, a first semiconductor chip 110, a second semiconductor chip 120, a third semiconductor chip 130, and a fourth semiconductor chip 140.

A plurality of first chip pads CP1 and a first identification pad array EPA1A may be provided on a top surface of the first semiconductor chip 110. A plurality of second chip pads CP2 and a second identification pad array EPA2A may be provided on a top surface of the second semiconductor chip 120. A plurality of third chip pads CP3 and a third identification pad array EPA3A may be provided on a top surface of the third semiconductor chip 130. A plurality of fourth chip pads CP4 and a fourth identification pad array EPA4A may be provided on a top surface of the fourth semiconductor chip 140.

A total of eight identification pads included in each of the plurality of identification pad arrays may be arranged in a 2×4 array. For example, four columns of identification pads may be arranged in a first direction, and two rows of identification pads may be arranged in a second direction. The electrical connection may be configured in the order of the first identification pad LP1, the second identification pad LP2, the third identification pad LP3, the fourth identification pad LP4, the fifth identification pad LP5, the sixth identification pad LP6, the seventh identification pad LP7, and the eighth identification pad LP8.

As shown in FIGS. 6A to 6D, the first identification pad LP1 included in the plurality of identification pads is connected to the ground GND on the first upper surface 111F. The second identification pad LP2 is arranged in a positive second direction with respect to the first identification pad LP1. The eighth identification pad LP8 connected to a power source V may be arranged in a negative first direction. The third identification pad LP3 is arranged in a negative first direction with respect to the second identification pad LP2, the fourth identification pad LP4 is arranged in a negative second direction with respect to the third identification pad LP3, the fifth identification pad LP5 is arranged in a negative first direction with respect to the fourth identification pad LP4, the sixth identification pad LP6 is arranged in a positive second direction with respect to the fifth identification pad LP5, the seventh identification pad LP7 is arranged in a negative first direction with respect to the sixth identification pad LP6, and the eighth identification pad LP8 may be arranged in a negative second direction with respect to the seventh identification pad LP7.

As shown in FIG. 6B, a first wire ball WB1 may be arranged on the first identification pad LP1 and the second identification pad LP2. A second gap G2 may have the same size as a first gap G1. The first gap G1 may be less than a first diameter D1, which is a diameter of the first wire ball WB1. For example, the size of the second gap G2 may be limited to less than about 25 μm. Alternatively, the size of the second gap G2 may be about 20 μm or more.

Since electric current passes through the first wire ball WB1 instead of the second resistor R2 due to the first wire ball WB1, the magnitude of the voltage applied across the first resistor R1 may be increased in the case of FIG. 6B having the first wire ball WB1 compared to the case of FIG. 6A without the first wire ball WB1. That is, the magnitude of the voltage measured at the measurement point MP may be greater in the case of FIG. 6B than in the case of FIG. 6A.

As shown in FIG. 6C, a second wire ball WB2 may be further arranged on the second identification pad LP2 and the third identification pad LP3. Since electric current passes through the second wire ball WB2 instead of the third resistor R3 due to the second wire ball WB2, the magnitude of the voltage applied across the first resistor R1 may be increased in the case of FIG. 6C having the second wire ball WB2 compared to the case of FIG. 6B without the second wire ball WB2.

As shown in FIG. 6D, a third wire ball WB3 may be further arranged on the third identification pad LP3 and the fourth identification pad LP4. Since electric current passes through the third wire ball WB3 instead of the fourth resistor R4 due to the third wire ball WB3, the magnitude of the voltage applied across the first resistor R1 may be increased in the case of FIG. 6D having the third wire ball WB3 compared to the case of FIG. 6C without the third wire ball WB3.

When four to seven wire balls of the semiconductor package 1A according to embodiments are arranged, detailed description thereof will be understood through FIGS. 3F and 3G described above. The overall size of the semiconductor package may be reduced through efficient space arrangement of identification pads in the semiconductor package 1A according to embodiments, and multiple semiconductor chips may be identified.

In some embodiments, instead of arranging a plurality of 2×4 identification pads of the semiconductor package 1A described above, arrangements having the same number of rows as the number of columns such as 2×2, 3×3, and the like, or various arrangements such as 2×3, 2×5, 3×2, 3×4, and the like may be possible. The number of identifiable semiconductor chips may vary according to each case. In addition, in some embodiments, two or more identification pad arrays may be provided per semiconductor chip. The detailed description of the semiconductor package 1A may be substantially the same as the description of the semiconductor package 1 described above.

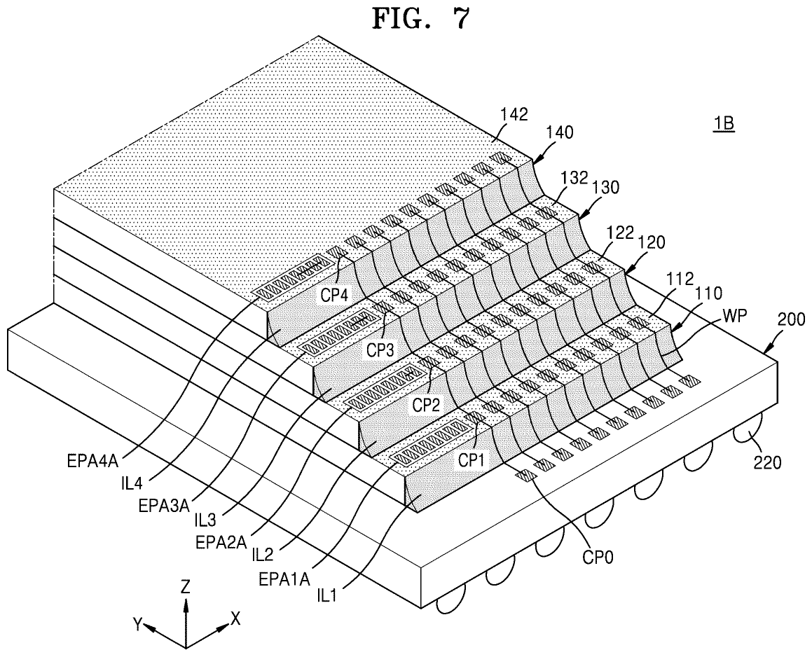

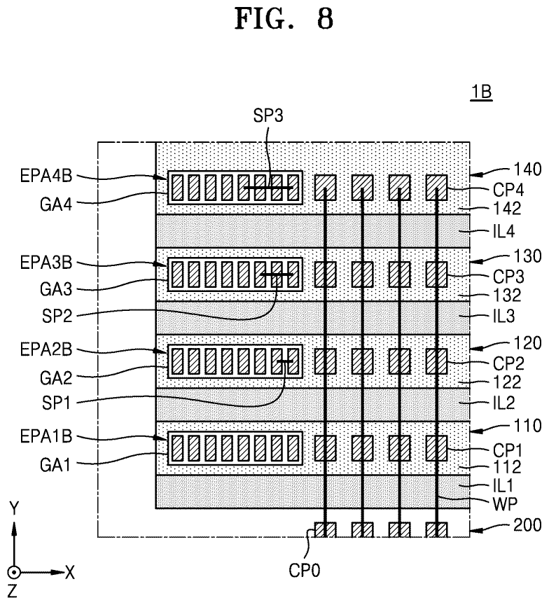

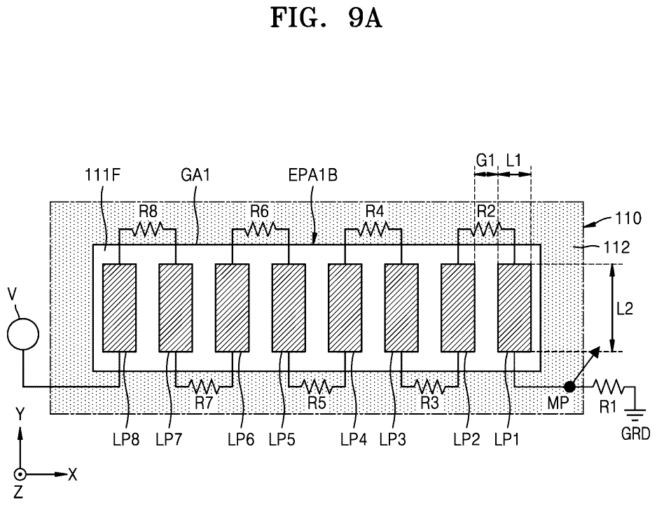

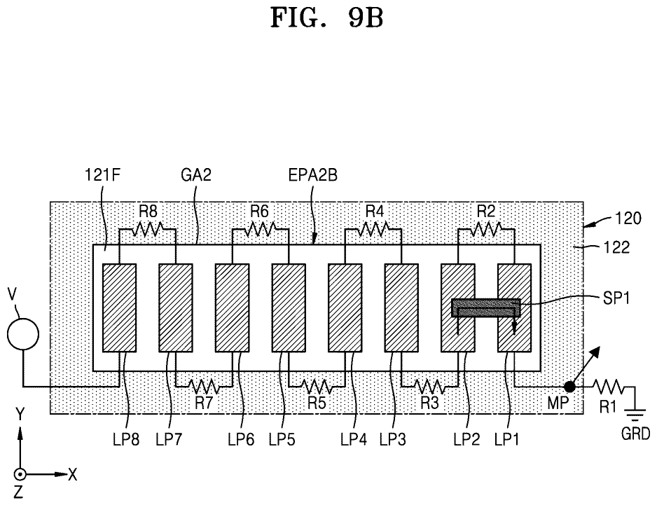

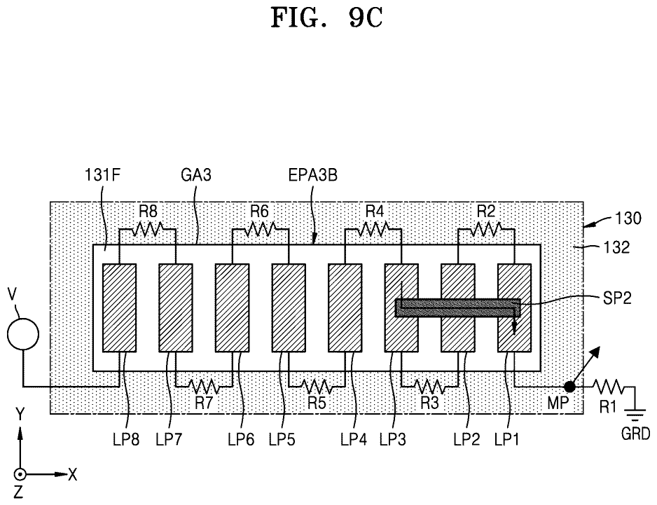

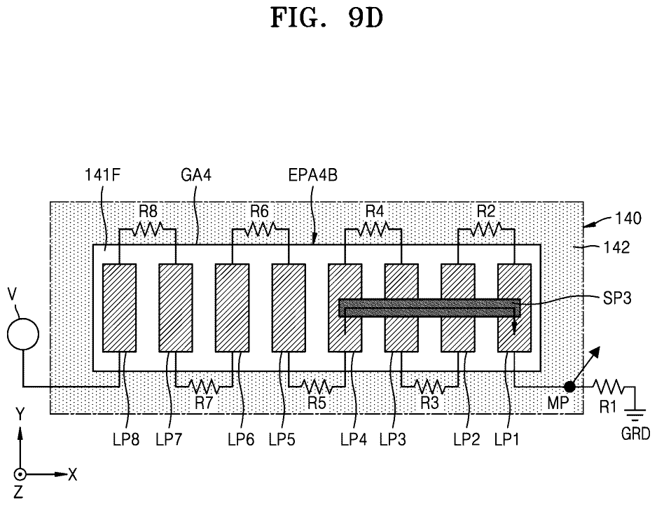

FIG. 7 is a perspective view showing a semiconductor package 1B according to embodiments. FIG. 8 is an enlarged plan view of a portion of a semiconductor package 1B according to embodiments. FIG. 9A is an enlarged plan view of a portion of a semiconductor package 1B according to embodiments. FIG. 9B is an enlarged plan view of a portion of a semiconductor package 1B according to embodiments. FIG. 9C is an enlarged plan view of a portion of a semiconductor package 1B according to embodiments. FIG. 9D is an enlarged plan view of a portion of a semiconductor package 1B according to embodiments. Hereinbelow, descriptions that are not separately given may be substantially the same as those described above.

Referring to FIGS. 7, 8, and 9A to 9D, a semiconductor package 1 according to embodiments may include a package substrate 200, a first semiconductor chip 110, a second semiconductor chip 120, a third semiconductor chip 130, and a fourth semiconductor chip 140.

A first insulating layer IL1 extending from a side surface of the first semiconductor chip 110 and a top surface of the package substrate 200 may be provided. The first insulating layer IL1 may cover a portion of the top surface of the package substrate 200 and extend from the side surface of the first semiconductor chip 110.

For example, the first insulating layer IL1 may be attached to a side surface of the first semiconductor chip 110 facing the plurality of substrate pads CP0, and between the plurality of substrate pads CP0 on the top surface of the package substrate 200, and the first semiconductor chip 110. The first insulating layer IL1 may be provided in a form that fills a step formed by the top surface of the package substrate 200 and the side surface of the first semiconductor chip 110.

A second insulating layer IL2 extending from a side surface of the second semiconductor chip 120 and top surface of the first semiconductor chip 110 may be provided. The second insulating layer IL2 may cover a portion of the top surface of the first semiconductor chip 110 and extend from the side surface of the second semiconductor chip 120. More specifically, the second insulating layer IL2 may be provided on the first passivation layer 112 arranged on the first semiconductor chip 110.

For example, the second insulating layer IL2 may be attached to a side surface of the second semiconductor chip 120 facing the plurality of first chip pads CP1 and between the plurality of first chip pads CP1 on the top surface of the first semiconductor chip 110 and the first semiconductor chip 110. The second insulating layer IL2 may be provided in a form that fills a step formed by the top surface of the first semiconductor chip 110 and the side surface of the second semiconductor chip 120.

A third insulating layer IL3 extending from a side surface of the third semiconductor chip 130 and a top surface of the second semiconductor chip 120 may be provided. The third insulating layer IL3 may cover a portion of the top surface of the second semiconductor chip 120 and extend from the side surface of the third semiconductor chip 130. The third insulating layer IL3 may be provided in a form that fills a step formed by the top surface of the second semiconductor chip 120 and the side surface of the third semiconductor chip 130.

A fourth insulating layer IL4 extending from a side surface of the fourth semiconductor chip 140 and a top surface of the third semiconductor chip 130 may be provided. The fourth insulating layer IL4 may cover a portion of the top surface of the third semiconductor chip 130 and extend from the side surface of the fourth semiconductor chip 140. The fourth insulating layer IL4 may be provided in a form that fills a step formed by the top surface of the third semiconductor chip 130 and the side surface of the fourth semiconductor chip 140.

A plurality of conductive patterns WP connecting at least a respective corresponding portion of the plurality of substrate pads CP0, the plurality of first chip pads CP1, the plurality of second chip pads CP2, the plurality of third chip pads CP3, and the plurality of fourth chip pads CP4, with each other, may be provided. The plurality of conductive patterns WP may extend on at least a respective portion of the top surface of the package substrate 200, the surface of the first insulating layer IL1, the top surface of the first semiconductor chip 110, the surface of the second insulating layer IL2, the top surface of the second semiconductor chip 120, the surface of the third insulating layer IL3, the top surface of the third semiconductor chip 130, the surface of the fourth insulating layer IL4, and the top surface of the fourth semiconductor chip 140.

The plurality of conductive patterns WP may electrically connect at least a respective corresponding portion of the plurality of substrate pads CP0, the plurality of first chip pads CP1, the plurality of second chip pads CP2, the plurality of third chip pads CP3, and the plurality of fourth chip pads CP4, with each other.

A plurality of first chip pads CP1 and a first identification pad array EPA1B may be provided on a top surface of the first semiconductor chip 110. A plurality of second chip pads CP2 and a second identification pad array EPA2B may be provided on a top surface of the second semiconductor chip 120. A plurality of third chip pads CP3 and a third identification pad array EPA3B may be provided on a top surface of the third semiconductor chip 130. A plurality of fourth chip pads CP4 and a fourth identification pad array EPA4B may be provided on a top surface of the fourth semiconductor chip 140.

As shown in FIG. 9A, there may be provided no identification pattern on the plurality of identification pads of the first semiconductor chip 110. Alternatively, as shown in FIG. 9B, a first identification pattern SP1 may be provided on some of the plurality of identification pads provided in the second semiconductor chip 120. The first identification pattern SP1 may extend on the first identification pad LP1 and the second identification pad LP2. The first identification pattern SP1 may be in contact with the first identification pad LP1, the second identification pad LP2, and the second top surface 121F.

As shown in FIG. 9C, a second identification pattern SP2 may extend on the first to third identification pads LP1, LP2 and LP3 on the third semiconductor chip 130. The second identification pattern SP2 may be in contact with the first to third identification pads LP1, LP2, and LP3 and the third top surface 131F.

As shown in FIG. 9D, a third identification pattern SP3 may extend on the first to fourth identification pads LP1, LP2, LP3 and LP4 on the fourth semiconductor chip 140. The third identification pattern SP3 may be in contact with the first to fourth identification pads LP1, LP2, LP3 and LP4 and the fourth top surface 141F.

In the second semiconductor chip 120, electric current may flow through the first identification pattern SP1, without passing through the second resistor R2; in the third semiconductor chip 130, electric current may flow through the second identification pattern SP2, without passing through the second resistor R2 and the third resistor R3; and in the fourth semiconductor chip 140, electric current may flow through the third identification pattern SP3, without passing through the second resistor R2, the third resistor R3, and the fourth resistor R4. Accordingly, a voltage applied across the first resistor R1 provided in each of the first to fourth semiconductor chips 110, 120, 130 and 140 may vary.

As the first identification pattern SP1, the second identification pattern SP2, and the third identification pattern SP3 are provided on the second semiconductor chip 120, the third semiconductor chip 130, and the fourth semiconductor chip 140, respectively, a voltage applied across the first resistor R1 may vary. Accordingly, since the magnitude of the voltage measured at the measurement point MP varies depending on the first to fourth semiconductor chips 110, 120, 130, and 140, each semiconductor chip may be identified.

The plurality of conductive patterns WP may be wired by a direct printing method. For example, the direct printing method may include screen printing, inkjet printing, or aerosol jet printing. Inkjet printing may spray droplets from nozzles and form conductive patterns through a heat/ultraviolet (UV) curing process. Aerosol jet printing may attach an aerosol to a surface in the form of very fine particles and form conductive patterns through a curing process. Screen printing may form a metal wiring by pushing a paste onto a patterned screen and drying and heat-treating the paste. Alternatively, a conductive pattern may be formed on the surface of the semiconductor chip through deposition.

In the process of forming the plurality of conductive patterns WP described above, the first identification pattern SP1, the second identification pattern SP2, and the third identification pattern SP3 may be formed together. That is, the types of materials included in the plurality of conductive patterns WP described above and the types of materials included in the first identification pattern SP1, the second identification pattern SP2, and the third identification pattern SP3 may be the same.

The overall size of the semiconductor package 1B may be reduced by enabling efficient space arrangement of identification pads through the identification pads in the semiconductor package 1B according to embodiments, and multiple semiconductor chips may be identified.

Although not shown in FIGS. 7, 8, and 9A to 9D, in the case of each of the identification pattern extending from the first to fifth identification pads LP1 to LP5, the identification pattern extending from the first to sixth identification pads LP1 to LP6, the identification pattern extending from the first to seventh identification pads LP1 to LP7, and the identification pattern extending from the first to eighth identification pads LP1 to LP8, the voltage applied across the first resistor R1 may vary. Accordingly, it will be understood from the above description that the semiconductor chip may be identified. An identification pattern may prevent electric current from passing through a resistor electrically connected between identification pads as the identification pattern extends longer on the identification pads. As may be seen from the drawings described above, it may be seen that the length varies for each identification pattern.

In some embodiments, the identification pad array may be provided between a semiconductor chip and another semiconductor chip. The identification pad array may be provided in a space where a semiconductor chip and another semiconductor chip are attached and stacked, and identification patterns may be arranged in the identification pad array before being stacked on the semiconductor chip, and then a stacking process of semiconductor chips may be performed. In the case of such an embodiment, the space of the semiconductor chip may be configured more efficiently.

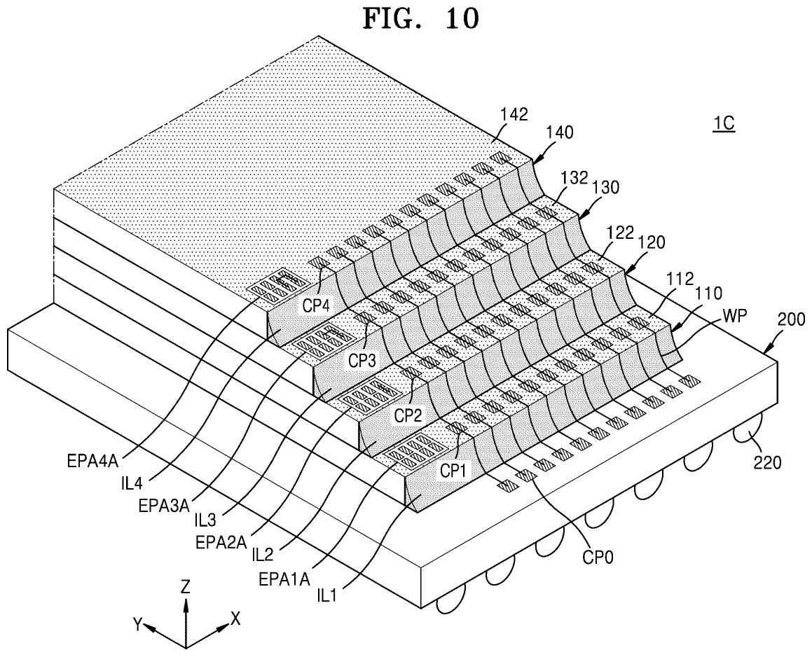

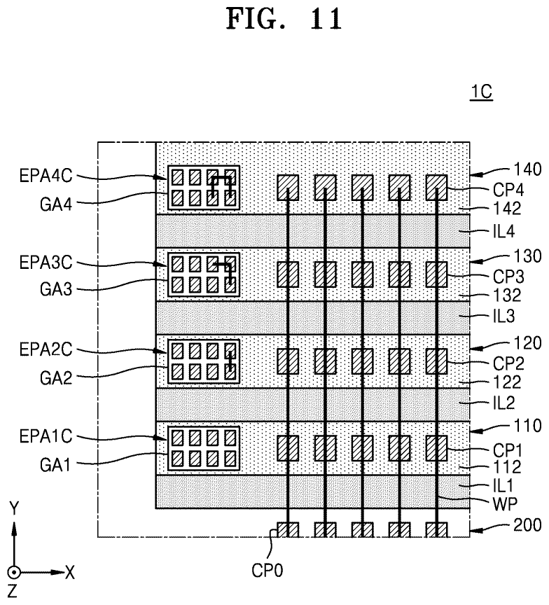

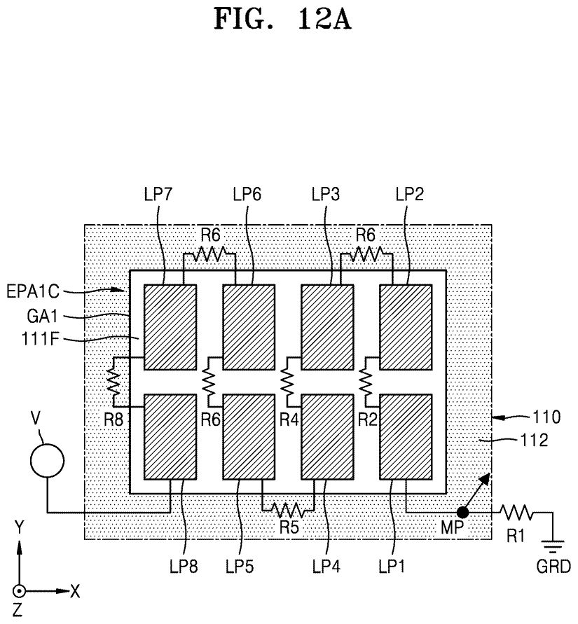

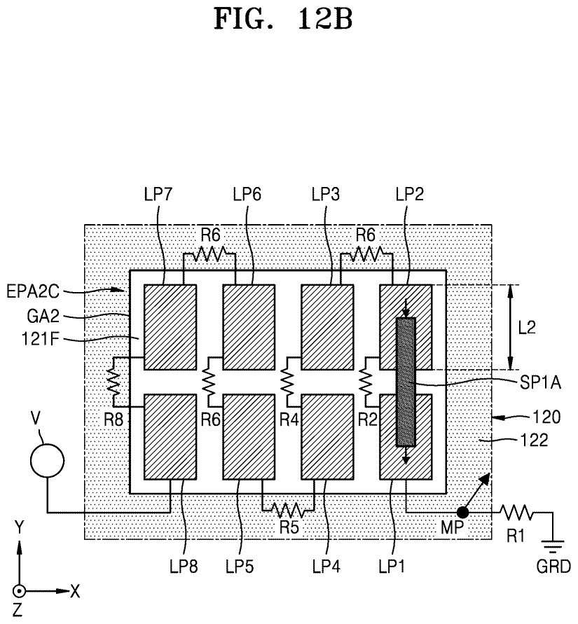

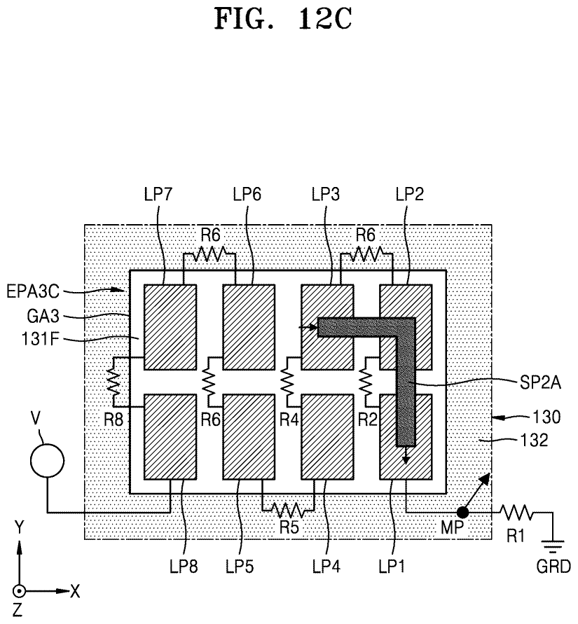

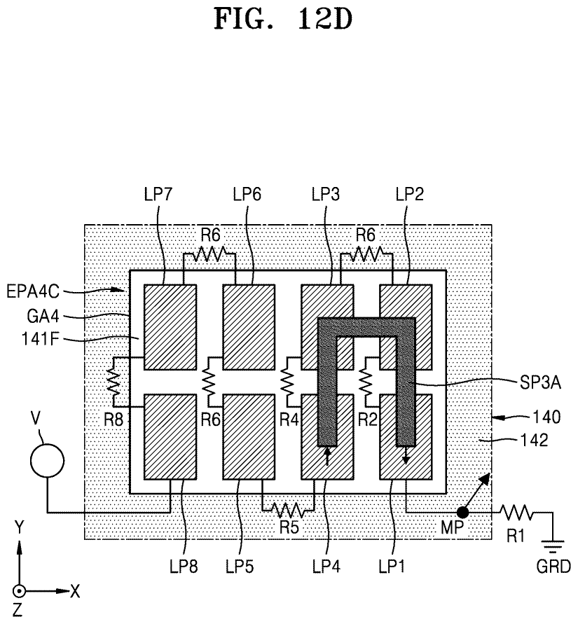

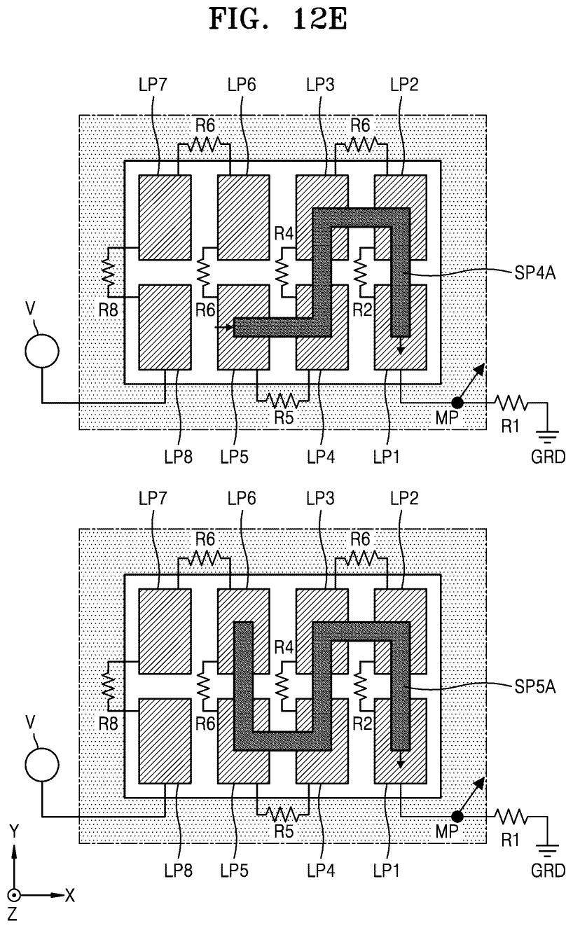

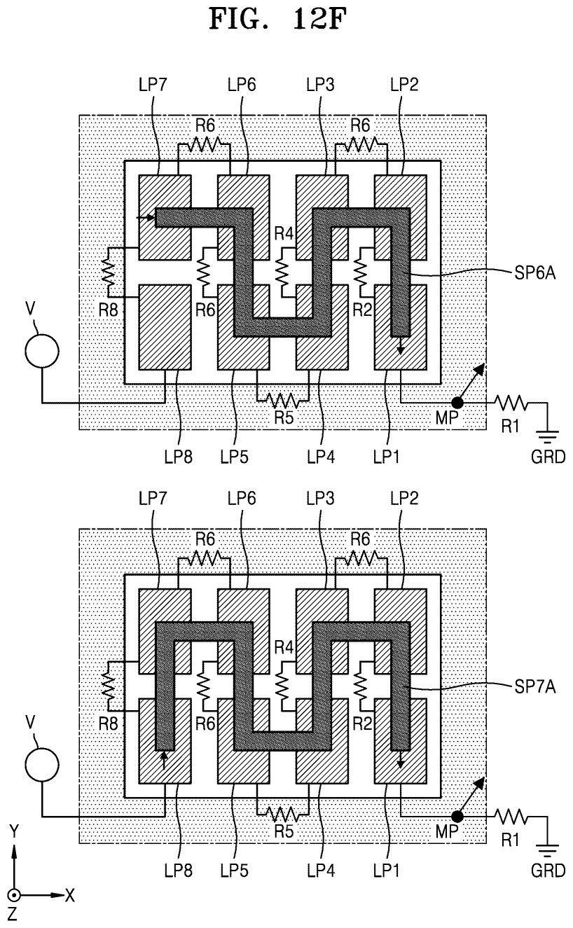

FIG. 10 is a perspective view showing a semiconductor package 1C according to embodiments. FIG. 11 is an enlarged plan view of a portion of a semiconductor package 1C according to embodiments. FIG. 12A is an enlarged plan view of a portion of a semiconductor package 1C according to embodiments. FIG. 12B is an enlarged plan view of a portion of a semiconductor package 1C according to embodiments. FIG. 12C is an enlarged plan view of a portion of a semiconductor package 1C according to embodiments. FIG. 12D is an enlarged plan view of a portion of a semiconductor package 1C according to embodiments. FIG. 12E is an enlarged plan view of a portion of a semiconductor package 1C according to embodiments. FIG. 12F is an enlarged plan view of a portion of a semiconductor package 1C according to embodiments. Hereinbelow, descriptions that are not separately given may be substantially the same as those described above.

Referring to FIGS. 10, 11, and 12A to 12D, a semiconductor package 1C according to embodiments may include a package substrate 200, a first semiconductor chip 110, a second semiconductor chip 120, a third semiconductor chip 130, and a fourth semiconductor chip 140.

A plurality of first chip pads CP1 and a first identification pad array EPA1C may be provided on a top surface of the first semiconductor chip 110. A plurality of second chip pads CP2 and a second identification pad array EPA2C may be provided on a top surface of the second semiconductor chip 120. A plurality of third chip pads CP3 and a third identification pad array EPA3C may be provided on a top surface of the third semiconductor chip 130. A plurality of fourth chip pads CP4 and a fourth identification pad array EPA4C may be provided on a top surface of the fourth semiconductor chip 140.

A total of eight identification pads included in each of the plurality of identification pad arrays may be arranged in a 2×4 array. For example, four columns of identification pads may be arranged in a first direction, and two rows of identification pads may be arranged in a second direction.

As shown in FIG. 12A, there may be provided no identification pattern on the plurality of identification pads of the first semiconductor chip 110. As shown in FIG. 12B, a first identification pattern SP1A may be provided on some of the plurality of identification pads provided in the second semiconductor chip 120. The first identification pattern SP1A may extend on the first identification pad LP1 and the second identification pad LP2. As shown in FIG. 12C, a second identification pattern SP2A may extend on the first to third identification pads LP1, LP2 and LP3 on the third semiconductor chip 130. As shown in FIG. 12D, a third identification pattern SP3A may extend on the first to fourth identification pads LP1, LP2, LP3 and LP4 on the fourth semiconductor chip 140.

In the second semiconductor chip 120, electric current may flow through the first identification pattern SP1A, without passing through the second resistor R2; in the third semiconductor chip 130, electric current may flow through the second identification pattern SP2A, without passing through the second resistor R2 and the third resistor R3; and in the fourth semiconductor chip 140, electric current may flow through the third identification pattern SP3A, without passing through the second resistor R2, the third resistor R3, and the fourth resistor R4. Resistors mentioned in the disclosure may be referred to as identification resistors, respectively. The first resistor R1 may be referred to as a reference resistor.

Accordingly, a voltage applied across the first resistor R1 provided in each of the first to fourth semiconductor chips 110, 120, 130 and 140 may vary. Since the magnitude of the voltage measured at the measurement point MP varies depending on the first to fourth semiconductor chips 110, 120, 130, and 140, each semiconductor chip may be identified. In the process of forming the plurality of conductive patterns WP described above, the first identification pattern SP1A, the second identification pattern SP2A, and the third identification pattern SP3A may be formed together.

The overall size of the semiconductor package 1C may be reduced by enabling efficient space arrangement of identification pads through the identification pads in the semiconductor package 1C according to embodiments, and multiple semiconductor chips may be identified.

Referring to FIG. 12E, a fourth identification pattern SP4A may extend on the first to fifth identification pads LP1 to LP5, and a fifth identification pattern SP5A may extend on the first to sixth identification pads LP1 to LP6.

Referring to FIG. 12F, a sixth identification pattern SP6A may extend on the first to seventh identification pads LP1 to LP7, and a seventh identification pattern SP7A may extend on the first to eighth identification pads LP1 to LP8.

When each of the first to seventh identification patterns SP1A, SP2A, SP3A, SP4A, SP5A, SP6A, and SP7A is provided, the voltage applied across the first resistor R1 may vary. Accordingly, it will be understood from the above description that the semiconductor chip may be identified.

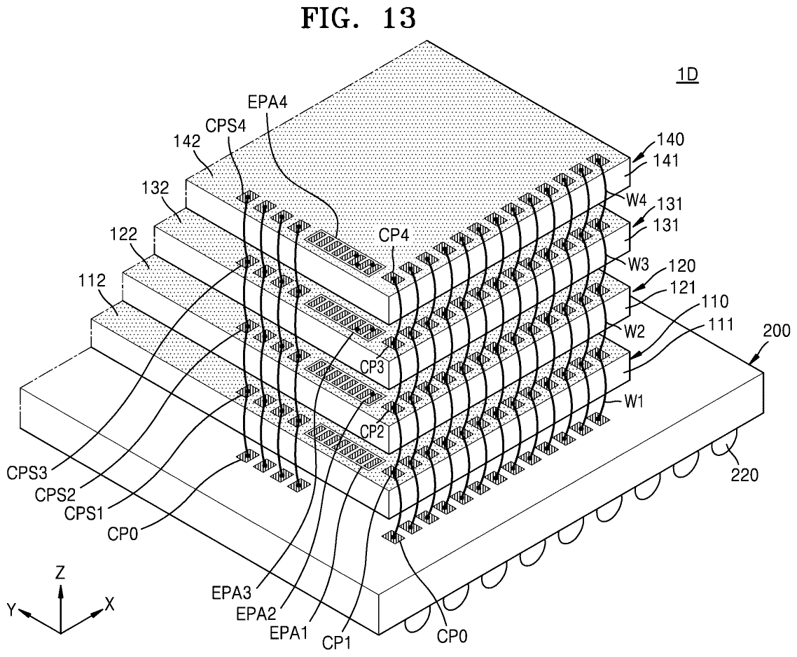

FIG. 13 is a perspective view showing a semiconductor package 1D according to embodiments. Descriptions that are not separately given may be substantially the same as those described above.

Referring to FIG. 13, a semiconductor package 1D according to embodiments may include a package substrate 200, a first semiconductor chip 110, a second semiconductor chip 120, a third semiconductor chip 130, and a fourth semiconductor chip 140.

The first to fourth semiconductor chips 110, 120, 130, and 140 may be laterally offset and sequentially stacked. The second semiconductor chip 120 may be laterally offset from the first semiconductor chip 110 and may be provided on the first semiconductor chip 110. For example, the second semiconductor chip 120 may be offset from the first semiconductor chip 110 in a fourth direction when viewed in a plan view. The fourth direction may mean a lateral direction in which the first direction and the second direction are synthesized.

Likewise, the third semiconductor chip 130 may be arranged on the second semiconductor chip 120, and the third semiconductor chip 130 may be offset in the fourth direction from the second semiconductor chip 120. The fourth semiconductor chip 140 may be arranged on the third semiconductor chip 130, and the fourth semiconductor chip 140 may be offset in the fourth direction from the third semiconductor chip 130.

A plurality of first to fourth chip pads CP1, CP2, CP3, and CP4 may be arranged on some portions of a top surface of each of the first to fourth semiconductor chips 110, 120, 130 and 140 which have been offset and exposed. A plurality of stacked semiconductor chip stacks may be offset in the fourth direction so that the plurality of first to fourth chip pads CP1, CP2, CP3, and CP4 may be arranged along edges of two adjacent semiconductor chips.

A plurality of first to fourth side chip pads CPS1, CPS2, CPS3, and CPS4 may be provided at other portions of top surfaces of the first to fourth semiconductor chips 110, 120, 130 and 140 that are offset and exposed, in which a plurality of first to fourth chip pads CP1, CP2, CP3, and CP4 are not arranged.

A plurality of first chip pads CP1 and a first identification pad array EPA1 may be provided on a top surface of the first semiconductor chip 110. The first identification pad array EPA1 may be provided on a portion of the top surface of another first semiconductor chip 110 on which a plurality of first chip pads CP1 are not arranged.

A plurality of first chip pads CP1 may be provided adjacent to an edge extending in the first direction from the top surface of the first semiconductor chip 110 exposed due to the offset of the second semiconductor chip 120, a plurality of first side chip pads CPS1 may be provided adjacent to an edge extending in the second direction, and a first identification pad array EPA1 may be provided adjacent to an edge extending in the second direction.

This arrangement may also be applied to a plurality of second chip pads CP2, a plurality of second side chip pads CPS2, and a second identification pad array EPA2 of the second semiconductor chip 120. In addition, this arrangement may be also applied to a plurality of third chip pads CP3, a plurality of third side chip pads CPS3, and a third identification pad array EPA3 of the third semiconductor chip 130, and may be also applied to a plurality of fourth chip pads CP4, a plurality of fourth side chip pads CPS4, and a fourth identification pad array EPA4.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate; and
a plurality of semiconductor chips stacked on the package substrate in a stepwise manner, wherein
each of the plurality of semiconductor chips includes a plurality of chip pads and an identification pad array,
the identification pad array includes a plurality of identification pads,
the plurality of identification pads are electrically connected in series,
an identification resistor is electrically connected between every two adjacent identification pads of the plurality of identification pads, the identification pad array includes no wire ball or includes at least one wire ball, and each wire ball, when present, is disposed on adjacent identification pads and electrically connects the adjacent identification pads to each other,
a power source is connected to one end of the series connection of the plurality of identification pads, a ground is connected to another end of the series connection of the plurality of identification pads, and
a reference resistor is provided between the plurality of identification pads and the ground.

2. The semiconductor package of claim 1, wherein the identification pad arrays respectively provided in the plurality of semiconductor chips include a different number of wire balls.

3. The semiconductor package of claim 1, wherein
each of the plurality of semiconductor chips includes a measurement point at which a voltage applied across the reference resistor is measured, and
each of the plurality of semiconductor chips is identified based on the voltage measured at the measurement point.

4. The semiconductor package of claim 1, wherein the plurality of identification pads have a rectangular shape with a long length in one direction, and the plurality of identification pads are aligned and provided in the identification pad array.

5. The semiconductor package of claim 1, wherein a diameter of the wire ball is greater in a plan view than a distance between the adjacent identification pads of the plurality of identification pads.

6. The semiconductor package of claim 1, wherein a size of each of the plurality of identification pads in one direction is smaller than a size of each of the plurality of chip pads in the one direction.

7. The semiconductor package of claim 1, wherein
a passivation layer is provided on a top surface of each of the plurality of semiconductor chips,
the passivation layer covers the top surface of each of the plurality of semiconductor chips,
the identification pad array is exposed upward from the passivation layer, and
the plurality of identification pads are spaced apart from the passivation layer.

8. The semiconductor package of claim 1, wherein the wire ball is in continuous contact with the two adjacent identification pads and a top surface of a semiconductor chip.

9. The semiconductor package of claim 1, wherein as more of the wire balls are arranged, the lower a magnitude of voltage applied across the reference resistor.

10. The semiconductor package of claim 1, wherein
a number of wire balls provided in the identification pad array provided in each of the plurality of semiconductor chips varies for each of the plurality of semiconductor chips, and
a maximum number of the wire balls is one less than a number of the identification pads provided in the identification pad array.

11. The semiconductor package of claim 1, further comprising
a plurality of conductive wires electrically connecting the plurality of chip pads to each other, provided in each of the plurality of semiconductor chips, wherein
the wire ball is a contact of at least one of the conductive wires.

12. The semiconductor package of claim 1, wherein the identification resistor and the reference resistor are embedded in the plurality of semiconductor chips.

13. The semiconductor package of claim 1, wherein, when viewed in a plan view, two or more of the plurality of identification pads are arranged in a first direction and two or more of the plurality of identification pads are arranged in a second direction perpendicular to the first direction.

14. The semiconductor package of claim 1, wherein each of the plurality of identification pads has an area smaller than that of each of the plurality of chip pads.

15. A semiconductor package comprising:
a package substrate; and
a plurality of semiconductor chips stacked on the package substrate in a stepwise manner, wherein
each of the plurality of semiconductor chips includes a plurality of chip pads and an identification pad array,
the identification pad array includes a plurality of identification pads,
the plurality of identification pads are electrically connected in series,
an identification resistor is provided between every two adjacent identification pads of the plurality of identification pads,
the plurality of identification pads and the identification resistor are electrically connected to each other,
the identification pad array includes no identification pattern or at least one identification pattern,
the identification pattern, when present, is disposed on two or more identification pads and electrically connects the two or more identification pads to each other,
a power source is connected to one end of the series connection of the plurality of identification pads,
a ground is connected to another end of the series connection of the plurality of identification pads,
a reference resistor is provided between the plurality of identification pads and the ground,
power from the power source is same in all of the plurality of semiconductor chips,
each of the plurality of semiconductor chips includes a measurement point at which a voltage applied across the reference resistor is measured, and
each of the plurality of semiconductor chips is identified based on the voltage measured at the measurement point.

16. The semiconductor package of claim 15, wherein the identification patterns provided in the identification pad arrays of the plurality of semiconductor chips have different lengths.

17. The semiconductor package of claim 15, further comprising:
a plurality of insulating layers provided in a stepped shape formed by side surfaces and upper surfaces of adjacent semiconductor chips among the plurality of semiconductor chips; and
a plurality of conductive patterns electrically connecting a plurality of chip pads to each other, provided in each of the plurality of semiconductor chips, wherein
the conductive patterns extend on the upper surfaces of the plurality of semiconductor chips and surfaces of the plurality of insulating layers.

18. The semiconductor package of claim 17, wherein the plurality of conductive patterns and the identification patterns are formed in a same process.

19. The semiconductor package of claim 15, wherein a resistance value decreases as a distance from the reference resistor to the identification resistor increases.

20. A semiconductor package comprising:
a package substrate; and
a plurality of semiconductor chips stacked on the package substrate in a stepwise manner, wherein
each of the plurality of semiconductor chips includes a plurality of chip pads and an identification pad array,
a plurality of conductive wires electrically connecting a plurality of chip pads provided in each of the plurality of semiconductor chips,
the identification pad array includes a plurality of identification pads,
the plurality of identification pads are electrically connected in series,
an identification resistor is electrically connected between every two adjacent identification pads of the plurality of identification pads,
the identification pad array includes no wire ball or includes at least one wire ball, and each wire ball, when present, connects the adjacent identification pads to each other, the wire ball is in continuous contact with two adjacent identification pads and a top surface of each of the semiconductor chips,
a power source is connected to one end of the series connection of the plurality of identification pads,
a ground is connected to another end of the series connection of the plurality of identification pads,
a reference resistor is provided between the plurality of identification pads and the ground,
the identification pad arrays respectively provided in the plurality of semiconductor chips include different numbers of wire balls,
each of the plurality of semiconductor chips includes a measurement point at which a voltage applied across the reference resistor is measured,
each of the plurality of semiconductor chips has a different voltage applied across the reference resistor,
a magnitude of the voltage applied across the reference resistor decreases as the number of wire balls increases,
the number of the wire balls provided in the identification pad array provided in each of the plurality of semiconductor chips varies for each of the plurality of semiconductor chips,
a maximum number of the wire balls is one less than the number of the identification pads provided in the identification pad array,
the wire ball is a contact point of at least one of conductive wires,
the plurality of identification pads are aligned, the plurality of identification pads have a rectangular shape having a long length in one direction,
a diameter of the wire ball is greater in a plan view than a distance between the adjacent identification pads of the plurality of identification pads,
sizes of the plurality of identification pads in one direction are smaller than sizes of the plurality of chip pads in the one direction,
a passivation layer is provided on a top surface of each of the plurality of semiconductor chips, the passivation layer covers the top surface of each of the plurality of semiconductor chips, the plurality of identification pads are spaced apart from the passivation layer,
a gap between every two adjacent identification pads of the plurality of identification pads falls within a range of about 20 μm to about 40 μm, and
a size of each of the identification pads in one direction is in a range of about 50 μm to about 80 μm.
